(19) United States
(12) Patent Application Publication
(10) Pub. No.: US 2023/0378370 A1
(43) Pub. Date: Nov. 23, 2023

(54) LIGHT-EMITTING COMPONENT, OPTICAL MEASUREMENT DEVICE, IMAGE FORMING APPARATUS, AND METHOD FOR MANUFACTURING LIGHT-EMITTING COMPONENT

(71) Applicant: FUJIFILM Business Innovation Corp., Tokyo (JP)

(72) Inventors: Takashi KONDO, Kanagawa (JP); Michiaki MURATA, Kanagawa (JP); Junichiro HAYAKAWA, Kanagawa (JP); Takafumi HIGUCHI, Kanagawa (JP)

(73) Assignee: FUJIFILM Business Innovation Corp., Tokyo (JP)

(21) Appl. No.: 18/362,003

(22) Filed: Jul. 31, 2023

Related U.S. Application Data
(63) Continuation of application No. PCT/JP2021/027298, filed on Jul. 21, 2021.

(30) Foreign Application Priority Data
Apr. 26, 2021 (JP) 2021-074496

(51) Int. Cl. H01L 29/786; B41J 2/45; H01L 27/15

(52) U.S. Cl. CPC H01L 29/7869; B41J 2/451; H01L 27/156

(57) ABSTRACT

A light-emitting component includes a substrate and a light-emitting element provided on the substrate and configured to emit light in a direction intersecting a surface of the substrate. The light-emitting element includes a thyristor having an opening through which light is emitted, and an inner surface of the opening is covered with a light shield that suppresses transmission of light.

### CROSS-REFERENCE TO RELATED APPLICATIONS

This is a continuation of International Application No. PCT/JP2021/027298 filed on Jul. 21, 2021, and claims priority from Japanese Patent Application No. 2021-074496 filed on Apr. 26, 2021.

### BACKGROUND

### (i) Technical Field

The present disclosure relates to a light-emitting component, an optical measurement device, an image forming apparatus, and a method for manufacturing the light-emitting component.

### (ii) Related Art

Japanese Unexamined Patent Application Publication No. 2001-308385 discloses a light-emitting device having a pnpnpn six-layer semiconductor structure. A p-type first layer and an n-type sixth layer at both ends, and a p-type third layer and an n-type fourth layer at the center are provided with electrodes, so that pn layers serve as a light-emitting diode, and pnpn layers serve as a thyristor.

Japanese Unexamined Patent Application Publication No. 1-238962 discloses a light-emitting element array in which a large number of light-emitting elements, whose threshold voltage or current can be controlled with light from the outside, are arranged one-, two-, or three-dimensionally. The light-emitting element array is configured such that at least a portion of light emitted from the light-emitting elements enter other adjacent light-emitting elements. A clock line for applying voltage or current from the outside is connected to the light-emitting elements.

Japanese Unexamined Patent Application Publication No. 2009-286048 discloses a self-scanning light source head and an image forming apparatus using the same. The self-scanning light source head includes a substrate, an array of surface-emitting semiconductor lasers provided on the substrate, and thyristors provided on the substrate and serving as switching elements for selectively turning on and off the emission of light from the surface-emitting semiconductor lasers.

### SUMMARY

A light-emitting unit having an array of light-emitting elements is used in 3D sensing or the like.

In some light-emitting devices, the light-emitting elements are turned on and set to a lighting state to emit light.

However, when some kind of light, for example, external light enters light-emitting elements in the off state, the light-emitting elements may be erroneously turned on. It is therefore desirable to prevent the light-emitting elements from being erroneously turned on even when receiving some kind of light.

Aspects of non-limiting embodiments of the present disclosure relate to providing a light-emitting component, an optical measurement device, an image forming apparatus, and a method for manufacturing the light-emitting component that are less likely to malfunction even when some kind of light enters a light-emitting element.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided a light-emitting component including: a substrate; and a light-emitting element provided on the substrate and configured to emit light in a direction intersecting a surface of the substrate, wherein the light-emitting element includes a thyristor having an opening through which light is emitted, and an inner surface of the opening is covered with a light shield that suppresses transmission of light.

### BRIEF DESCRIPTION OF THE DRAWINGS

Exemplary embodiments of the present disclosure will be described in detail based on the following figures, wherein:

FIG. 1 is an equivalent circuit diagram of a light-emitting device;

FIG. 2 shows an example planar layout of a light-emitting unit;

FIGS. 3A and 3B are sectional views of drive thyristors/laser diodes;

FIG. 4 is an enlarged plan view of a drive thyristor/laser diode;

FIG. 5 is a sectional view of an island including a setting thyristor and a connection diode and an island including a transfer thyristor, a coupling diode, and a connection diode;

FIGS. 6A and 6B show the case where an exit-surface protective film covers a smaller area of a cylindrical inner surface of an opening when the inner surface is viewed from above;

FIGS. 7A and 7B show the case where the exit-surface protective film covers a gate layer of the setting thyristor;

FIGS. 8A and 8B show the case where the exit-surface protective film covers an n-cathode layer of the setting thyristor;

FIGS. 9A and 9B show a second example of the other form of the exit-surface protective film;

FIGS. 10A and 10B show a third example of the other form of the exit-surface protective film;

FIGS. 11A and 11B show a fourth example of the other form of the exit-surface protective film;

FIGS. 12A to 12C show a stacked structure of the laser diode and the drive thyristor in more detail;

FIGS. 13A and 13B are flowcharts showing the orders of steps in the method for manufacturing the light-emitting unit;

FIG. 14 shows an example control of lighting and non-lighting of the laser diodes in the light-emitting device;

FIG. 15 is a timing chart for driving the light-emitting device;

FIG. 16 shows an optical measurement device using the light-emitting device; and

FIG. 17 shows an image forming apparatus using the light-emitting device.

### DETAILED DESCRIPTION

Exemplary embodiments of the present disclosure will be described in detail below with reference to the accompanying drawings.

### Light-Emitting Device 10

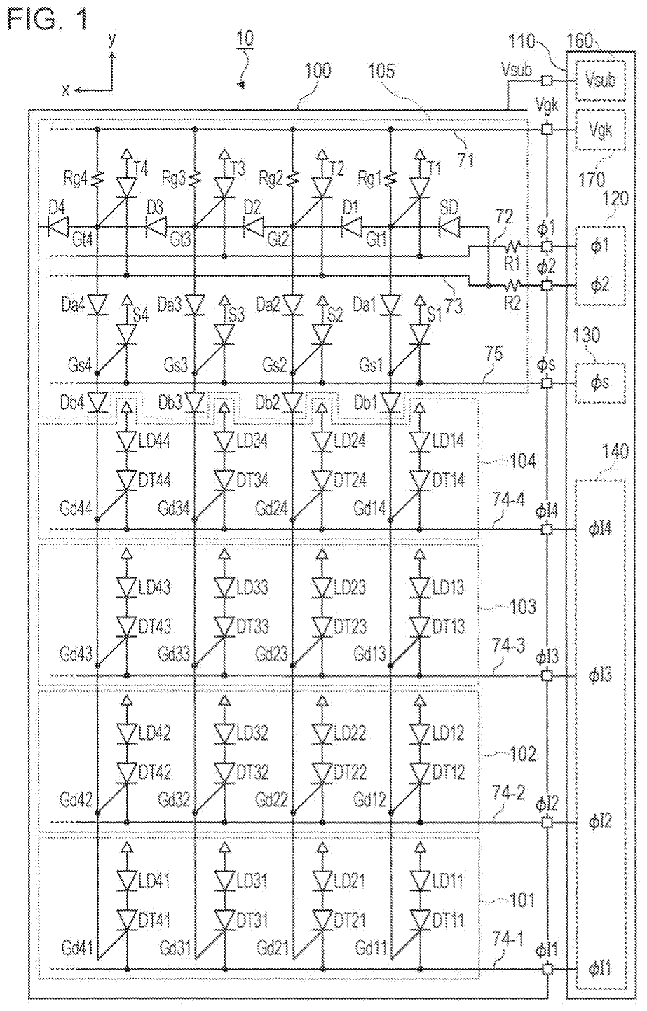

FIG. 1 is an equivalent circuit diagram of a light-emitting device 10.

The light-emitting device 10 includes a light-emitting unit 100 and a controller 110.

The light-emitting unit 100 includes laser diodes LD, which are an example of light-emitting elements, that emit laser beams. The light-emitting unit 100 is formed as a self-scanning light-emitting device (SLED) array, as described below. The laser diodes LD are, for example, vertical-cavity surface-emitting lasers (VCSELs).

In FIG. 1, the light-emitting unit 100 is an example of a light-emitting component and includes 16 laser diodes LD, which are arranged in a four by four matrix, or two-dimensionally.

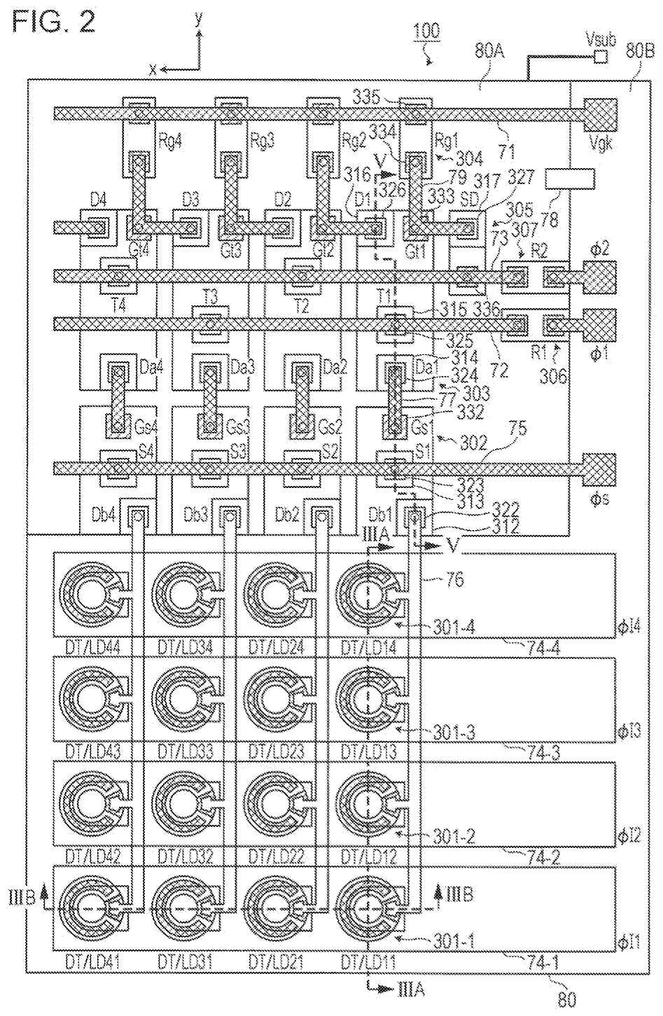

What is meant by two-dimensionally is that something has two dimensions and extends in, for example, the x and y directions, as described below. In the plane of the drawing of FIG. 1, the direction from the right to the left is defined as the x direction, and the direction from the bottom to the top is defined as the y direction. The x and y directions are orthogonal to each other. A light-emitting element unit 101 includes laser diodes LD11, LD21, LD31, and LD41 arranged in the x direction, a light-emitting element unit 102 includes laser diodes LD12, LD22, LD32, and LD42 arranged in the x direction, a light-emitting element unit 103 includes laser diodes LD13, LD23, LD33, and LD43 arranged in the x direction, and a light-emitting element unit 104 includes laser diodes LD14, LD24, LD34, and LD44 arranged in the x direction. The light-emitting element units 101 to 104 serve as light-emitting elements that are provided on a substrate 80 (see FIG. 2 described below) and emit light in a direction intersecting a surface of the substrate 80. The “surface” is a front or back surface of the substrate 80.

One laser diode LD included in the light-emitting element unit 101, one laser diode LD included in the light-emitting element unit 102, one laser diode LD included in the light-emitting element unit 103, and one laser diode LD included in the light-emitting element unit 104 are arranged in the y direction. More specifically, the laser diodes LD11, LD12, LD13, and LD14 are arranged in the y direction, the laser diodes LD21, LD22, LD23, and LD24 are arranged in the y direction, the laser diodes LD31, LD32, LD33, and LD34 are arranged in the y direction, and the laser diodes LD41, LD42, LD43, and LD44 are arranged in the y direction.

When the laser diodes LD are distinguished from one another as above, two-digit numbers are added (for example, “LD11”), where the number at the tens place represents the number in the x direction, and the number at the ones place represents the number in the y direction. Letters “i” and “j” may be used instead of the numbers in the x and y directions, respectively (for example, “LDij”). When only the numbers in the x direction are to be added, “i” may be used instead of the individual numbers, and when only the numbers in the y direction are to be added, “j” may be used instead of the individual numbers (the same rule applies to other reference signs). The letters “i” and “j” are integers of 1 to 4.

The light-emitting unit 100 includes 16 drive thyristors DT. The drive thyristors DT are connected to the corresponding laser diodes LD. The drive thyristors DT and the corresponding laser diodes LD are connected in series. In other words, the drive thyristors DT and the laser diodes LD form pairs. Hence, the same numbers as those of the corresponding laser diodes LD are added to the drive thyristors DT to distinguish the drive thyristors DT from one another.

The light-emitting unit 100 includes a transfer element unit 105 including four transfer thyristors T, four setting thyristors S, four coupling diodes D, four connection diodes Da, four connection diodes db, and four resistors Rg. The transfer element unit 105 also includes a start diode SD and current limiting resistors R1 and R2.

The transfer thyristors T1, T2, T3, and T4 are arranged in this order in the x direction. The coupling diodes D1, D2, D3, and D4 are arranged in this order in the x direction. The coupling diodes D1, D2, and D3 are provided between the transfer thyristors T1, T2, T3, and T4, and the coupling diode D4 is provided on the opposite side of the transfer thyristor T4 from the coupling diode D3.

The setting thyristors S1, S2, S3, and S4 are arranged in this order in the x direction.

The connection diodes Da and db and the resistors Rg are also arranged in the x direction.

Because the transfer thyristors T, the setting thyristors S, the coupling diodes D, the connection diodes Da and db, and the resistors Rg are arranged in the x direction, one digit numbers are added thereto. The letter “i” may be used instead of the individual numbers.

The laser diodes LD, the coupling diodes D, and the connection diodes Da and db are two-terminal elements each including an anode and a cathode. The drive thyristors DT, the transfer thyristors T, and the setting thyristors S are three-terminal elements each including an anode, a cathode, and a gate. The gates of the drive thyristors DTij (i, j=1 to 4) are referred to as gates Gdij, the gates of the transfer thyristors Ti (i=1 to 4) are referred to as gates Gti, and the gates of the setting thyristors Si (i=1 to 4) are referred to as gates Gsi for distinguishing.

The drive thyristors DT are an example of drive elements, the transfer thyristors T are an example of transfer elements, and the setting thyristors S are an example of setting elements.

Next, the connection relationship among these elements (the laser diodes LD, the drive thyristors DT, the transfer thyristors T, etc.) will be described.

As described above, the laser diodes LDij (i, j=1 to 4) and the corresponding drive thyristors DTij are connected in series. More specifically, the anodes of the laser diodes LDij are connected to the reference potential Vsub, such as the ground potential (GND), and the cathodes thereof are connected to the anodes of the drive thyristors DTij.

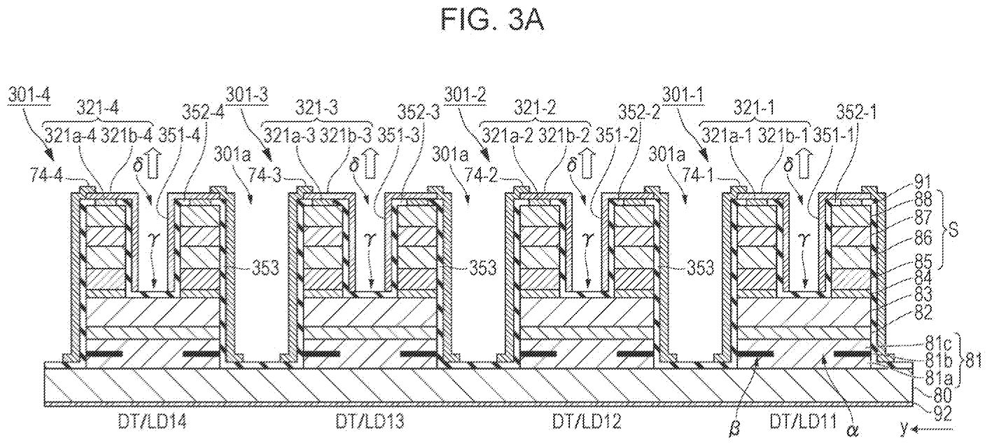

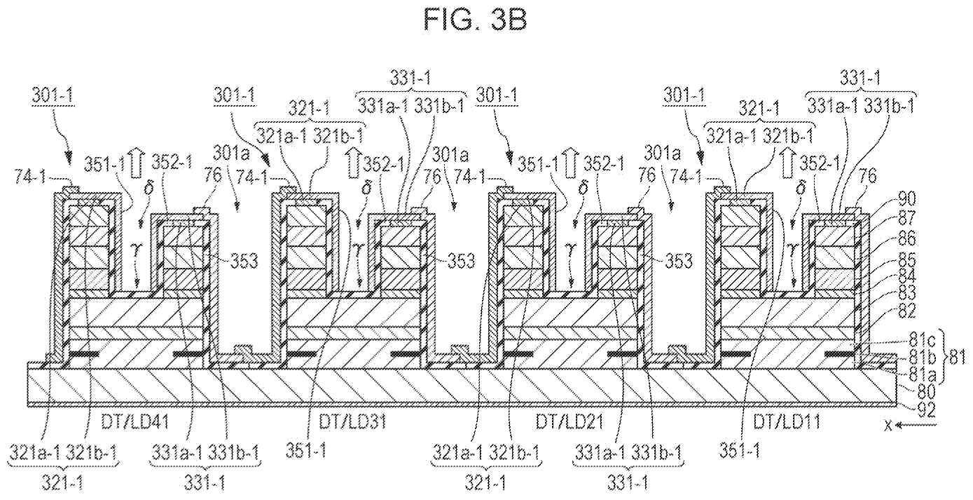

As will be described below, the reference potential Vsub is supplied via a back-surface electrode 92 (see FIG. 3 described below) provided on the back surface of the substrate 80 constituting the light-emitting unit 100.

The cathodes of the drive thyristors DTi1 included in the light-emitting element unit 101 are connected to a lighting signal wire 74-1. The lighting signal wire 74-1 is connected to a φI1 terminal and supplied with a lighting signal φI1 from the controller 110.

The cathodes of the drive thyristors DTi2 included in the light-emitting element unit 102 are connected to a lighting signal wire 74-2. The lighting signal wire 74-2 is connected to a φI2 terminal and is supplied with a lighting signal φI2 from the controller 110.

The cathodes of the drive thyristors DTi3 included in the light-emitting element unit 103 are connected to a lighting signal wire 74-3. The lighting signal wire 74-3 is connected to a φI3 terminal and is supplied with a lighting signal φI3 from the controller 110.

The cathodes of the drive thyristors DTi4 included in the light-emitting element unit 104 are connected to a lighting signal wire 74-4. The lighting signal wire 74-4 is connected to a φI4 terminal and is supplied with a lighting signal φI4 from the controller 110.

In short, the cathodes of the drive thyristors DTij are connected to the lighting signal wires 74-j, and the lighting signal wires 74-j are connected to the φIj terminals. The lighting signals φIj are supplied from the controller 110 to the φIj terminals.

In the transfer element unit 105, the anodes of the transfer thyristors Ti are connected to the reference potential Vsub. The cathodes of the odd-numbered transfer thyristors, T1 and T3, are connected to a transfer signal wire 72. The transfer signal wire 72 is connected to a terminal φ1 via the current limiting resistor R1 and is supplied with a transfer signal φ1 from the controller 110. The cathodes of the even-numbered transfer thyristors, T2 and T4, are connected to a transfer signal wire 73. The transfer signal wire 73 is connected to a terminal φ2 via the current limiting resistor R2 and is supplied with a transfer signal φ2 from the controller 110.

The coupling diodes Di are connected in series. More specifically, the cathodes of the coupling diodes D are connected to the anodes of the coupling diodes D adjacent thereto in the x direction. The anode of the start diode SD is connected to the transfer signal wire 73, and the cathode of the start diode SD is connected to the anode of the coupling diode D1.

The cathode of the start diode SD and the anode of the coupling diode D1 are connected to the gate Gt1 of the transfer thyristor T1. The cathode of the coupling diode D1 and the anode of the coupling diode D2 are connected to the gate Gt2 of the transfer thyristor T2. The cathode of the coupling diode D2 and the anode of the coupling diode D3 are connected to the gate Gt3 of the transfer thyristor T3. The cathode of the coupling diode D3 and the anode of the coupling diode D4 are connected to the gate Gt4 of the transfer thyristor T4.

The anodes of the setting thyristors Si (i=1 to 4) are connected to the reference potential Vsub, and the cathodes thereof are connected to a setting signal wire 75. The setting signal wire 75 is connected to a terminal φs and is supplied with a setting signal φs from the controller 110.

The gates Gti of the transfer thyristors Ti are connected to a power supply wire 71 via the resistors Rg. The power supply wire 71 is connected to a Vgk terminal and is supplied with a power supply potential Vgk (for example, −3.3 V) from controller 110.

The gates Gti of the transfer thyristors Ti are connected to the gates of the setting thyristors Si via the connection diodes Dai. The gates Gsi of the setting thyristors Si are connected to the gates Gdij of the drive thyristors DTij via the connection diodes Dbi.

That is, multiple (here, four) pairs of the drive thyristor DT and the laser diode LD are connected to each connection thyristor S.

The configuration of the controller 110 will be described.

The controller 110 generates signals, such as the lighting signals φIj, and supplies the signals to the light-emitting unit 100. The light-emitting unit 100 is operated by the supplied signals. The controller 110 includes an electronic circuit. For example, the controller 110 includes an integrated circuit (IC).

The controller 110 includes a transfer-signal generation unit 120, a setting-signal generation unit 130, a lighting-signal generation unit 140, a reference-potential generation unit 160, and a power-supply-potential generation unit 170.

The transfer-signal generation unit 120 generates the transfer signals φ1 and φ2 and supplies the transfer signals φ1 and φ2 to the φ1 and φ2 terminals of the light-emitting unit 100, respectively.

The setting-signal generation unit 130 generates the setting signal φs and supplies the signal to the φs terminal of the light-emitting unit 100.

The lighting-signal generation unit 140 generates the lighting signals φIj and supplies the lighting signals to the φIj terminals of the light-emitting unit 100.

The reference-potential generation unit 160 generates the reference potential Vsub and supplies the potential to the Vsub terminal of the light-emitting unit 100. The power-supply-potential generation unit 170 generates the power supply potential Vgk and supplies the potential to the Vgk terminal of the light-emitting unit 100.

The signals generated by the transfer-signal generation unit 120, the setting-signal generation unit 130, the lighting-signal generation unit 140, the reference-potential generation unit 160, and the power-supply-potential generation unit 170 will be described below.

Although the light-emitting unit 100 has been described to include the laser diodes LD arranged two-dimensionally in a four by four matrix, the number of the laser diodes LD per row and column is not limited to four. The values for i and j in i×j may be multiple values other than four. The number of the transfer thyristors T and the number of setting thyristors S only need to be i. The number of the transfer thyristors T and the number of the setting thyristors S may be either a number exceeding i or a number less than i.

### Layout of Light-Emitting Unit 100

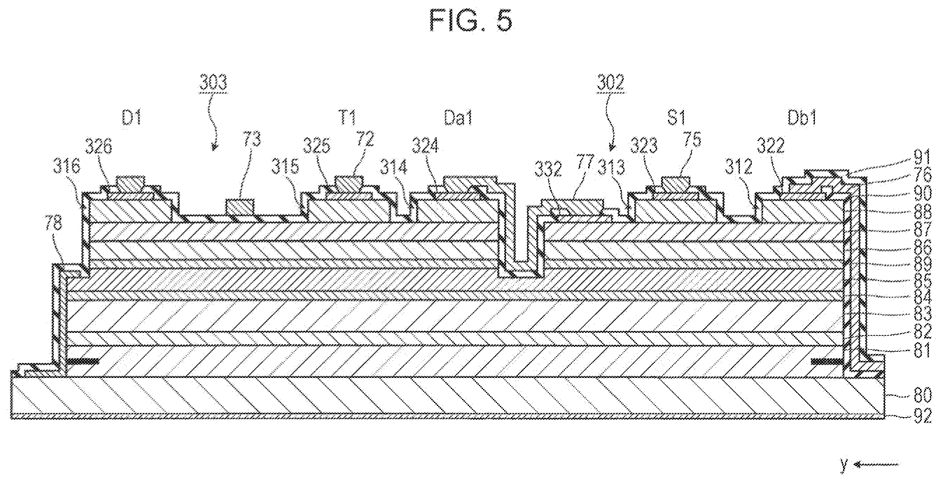

The light-emitting unit 100 is made of a semiconductor material capable of emitting a laser beam. For example, the light-emitting unit 100 is made of GaAs-based compound semiconductors. Specifically, as shown in FIGS. 3A, 3B, and 5 described below, the light-emitting unit 100 is formed of a semiconductor layer stack, in which multiple GaAs-based compound semiconductor layers are stacked on the substrate 80, which is made of p-type GaAs. The substrate 80 is supplied with the reference potential Vsub at the back-surface electrode 92 formed on the back surface of the substrate 80 and is set to the reference potential Vsub. First, a planar layout of the light-emitting unit 100 will be described.

FIG. 2 shows an example planar layout of the light-emitting unit 100.

The planar layout of the light-emitting unit 100 will be described by using islands 301 to 307 shown in FIG. 2. The islands are the structures formed by dividing a semiconductor layer stack into several portions by mesa etching.

The islands 301 include islands 301-j (j=1 to 4) each having a laser diode LD1j and a drive thyristor DT1j. The laser diode LD1j and the drive thyristor DT1j are stacked, thereby being connected in series. Thus, in FIG. 2, the laser diodes LD1j and the drive thyristors DT1j are denoted by DT/LD1j. Multiple islands similar to the islands 301 (islands 301-j) are provided parallel to the islands 301 (islands 301-j) in the x direction, and these islands have DT/LDij (i=2 to 4, j=1 to 4).

The island 302 has a connection diode Db1 and a setting thyristor S1. Multiple islands similar to the island 302 are provided parallel to the island 302 in the x direction, and these islands have the connection diodes Dbi (i=2 to 4) and the setting thyristors Si (i=2 to 4).

The island 303 has a connection diode Da1, a transfer thyristor T1, and a coupling diode D1. Multiple islands similar to the island 303 are provided parallel to the island 303 in the x direction, and these islands have the connection diodes Dai (i=2 to 4), the transfer thyristors Ti (i=2 to 4), and the coupling diodes Di (i=2 to 4).

The island 304 has a resistor Rg1. Multiple islands similar to the island 304 are provided parallel to the island 304 in the x direction, and these islands have resistors Rgi (i=2 to 4).

The island 305 has the start diode SD. The island 306 has the current limiting resistor R1, and the island 307 has the current limiting resistor R2.

The sectional structure of the light-emitting unit 100 will now be described.

FIGS. 3A and 3B are sectional views of the drive thyristors DT/laser diodes LD. FIG. 3A is a sectional view taken along line IIIA-IIIA in FIG. 2, and FIG. 3B is a sectional view taken along line IIIB-IIIB in FIG. 2.

As shown in FIG. 3A, on the substrate 80 made of p-type GaAs are stacked a p-type anode layer (hereinbelow, p-anode layer) 81, a light-emitting layer 82, and an n-type cathode layer (n-cathode layer) 83, which together constitute a laser diode LD. A tunnel junction layer 84 is stacked on the n-cathode layer 83 constituting the laser diode LD. On the tunnel junction layer 84 are provided a p-type anode layer (p-anode layer) 85, an n-type gate layer (n-gate layer) 86, a p-type gate layer (p-gate layer) 87, and an n-type cathode layer (n-cathode layer) 88, which constitute a drive thyristor DT. The thus-formed semiconductor layer stack is divided into islands by mesa etching.

The n-cathode layer 88, the p-gate layer 87, the n-gate layer 86, the p-anode layer 85, and the tunnel junction layer 84 at the center of each laser diode LD are removed by etching to form an opening δ, through which light is emitted. Thus, the n-cathode layer 83 of the laser diode LD is exposed. This exposed portion of the n-cathode layer 83 is a light emission port γ of the laser diode LD.

In this semiconductor layer stack, the light emission port γ of the laser diode LD is surrounded by the setting thyristor S. In other words, the p-anode layer 85, the n-gate layer 86, the p-gate layer 87, and the n-cathode layer 88, which have a thyristor structure, remain around the opening δ.

The p-anode layer 81 of the laser diode LD includes a current confinement layer. The current confinement layer is a layer in which aluminum is oxidized to Al₂O₃, increasing the electric resistance and making it difficult for a current to flow, as in AlAs. Because oxidation proceeds from the portion exposed by mesa etching (peripheral portion), the central portion is not oxidized. So, a region where a current easily flows (current passing region a) is left in the central portion, and a region where a current is difficult to flow due to oxidation (current blocking region B) is formed in the peripheral portion. Non-radiative recombination is likely to occur in the peripheral portion, where many defects are caused by mesa etching. Providing the current blocking region R reduces the power consumed by non-radiative recombination. Hence, the power consumption is reduced, and the light extraction efficiency is improved. The light extraction efficiency is the light intensity that can be extracted per power.

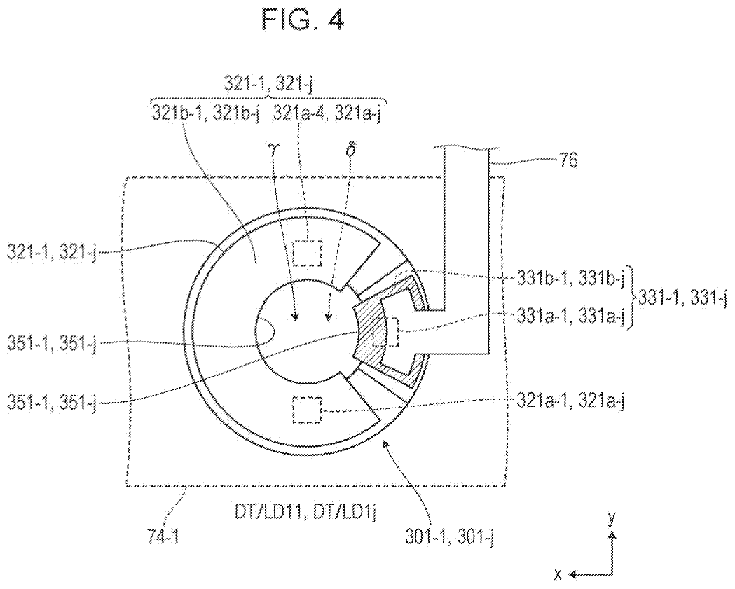

On the n-cathode layer 88, an n-ohmic electrode 321 (n-ohmic electrode 321-1, 321-2, 321-3, 321-4) made of metal that easily forms ohmic contact with the n-cathode layer 88 is provided. The n-ohmic electrode 321 is provided in a horseshoe shape (see FIG. 4 described below) so as to surround the emission port γ, through which a laser beam, indicated by an arrow, is emitted. An insulating layer 91 is provided on the portion other than the n-ohmic electrode 321. The lighting signal wire 74 (lighting signal wire 74-1, 74-2, 74-3, 74-4) is provided on the insulating layer 91 so as to be connected to the n-ohmic electrode 321. The lighting signal wire 74-1 is connected to the n-ohmic electrode 321-1 at the drive thyristor DT11/laser diode LD11, the lighting signal wire 74-2 is connected to the n-ohmic electrode 321-2 at the drive thyristor DT12/laser diode LD12, the lighting signal wire 74-3 is connected to the n-ohmic electrode 321-3 at the drive thyristor DT13/laser diode LD13, and the lighting signal wire 74-4 is connected to the n-ohmic electrode 321-4 at the drive thyristor DT14/laser diode LD14.

The inner surfaces of the openings δ are covered with exit-surface protective films 351-1, 351-2, 351-3, and 351-4 (hereinbelow, sometimes “exit-surface protective films 351”). The exit-surface protective films 351 are an example of light shields that suppress transmission of light. The “light shield” is a substance that blocks light and suppresses transmission of light. The “inner surfaces” are the side surfaces of the openings S. The inner surfaces are cylindrical.

The exit-surface protective films 351 only need to cover the inner surfaces of the openings δ and do not need to be provided on the bottom surfaces of the openings δ. If the exit-surface protective films 351 are provided on the bottom surfaces of the opening δ, the emitted light may be absorbed. In the example in FIG. 3, the exit-surface protective films 351 are not provided on the bottom surfaces of the openings δ.

The n-ohmic electrodes 321-1, 321-2, 321-3, and 321-4 include contact vias 321a-1, 321a-2, 321a-3, and 321a-4 (hereinbelow, sometimes simply “contact vias 321a”) and contact metals 321b-1, 321b-2, 321b-3, and 321b-4 (hereinbelow, sometimes simply “contact metals 321b”), respectively. The exit-surface protective films 351 extend from the contact metals 321b and are formed on the inner surfaces of the openings δ.

The p-ohmic electrodes 331-1 include contact vias 331a-1 and contact metals 331b-1. The exit-surface protective films 351 extend from the contact metals 331b and are formed on the inner surfaces of the openings δ.

It can also be said that the n-ohmic electrodes 321 and p-ohmic electrodes 332, which are the electrodes electrically connected to the setting thyristors S, extend to the inner surfaces of the openings S to form the exit-surface protective films 351. That is, the exit-surface protective films 351 provided on the inner surfaces of the openings δ are the n-ohmic electrodes 321 and the p-ohmic electrodes 331 extending to the inner surfaces of the openings δ. In other words, the exit-surface protective films 351 are formed as integral parts of the n-ohmic electrodes 321 and the p-ohmic electrodes 331.

As described above, the exit-surface protective films 351 are light shields. The light shields may be anything that suppresses transmission of light. For example, the light shield is a light absorber that absorbs light. Alternatively, the light shield is a light reflector that reflects light. The light absorbed or reflected by the exit-surface protective films 351 is, for example, the external light entering from the outside. That is, there is a case where at least one of the layers constituting the setting thyristor S absorbs light having a longer wavelength than the emitted light. There also is a case where at least one of the layers constituting the setting thyristor S absorbs light emitted from the light-emitting layer 82. When light having such a wavelength enters the openings δ and is absorbed by the setting thyristors S, the setting thyristors S may be turned on due to the energy of the light. The setting thyristors S remain in the on state due to their characteristics. This leads to malfunction of the setting thyristors S. In this exemplary embodiment, malfunction of the setting thyristors S is prevented by providing the exit-surface protective films 351 for blocking light.

The exit-surface protective films 351 are desirably made of metal. Examples of the metal include gold (Au), platinum (Pt), germanium (Ge), nickel (Ni), zinc (Zn), chromium (Cr), and titanium (Ti). An alloy containing these metals may also be used. The exit-surface protective films 351 made of metal not only absorb light but also reflect light, and thus can effectively block light.

When the exit-surface protective films 351 are made of metal, insulating portions 352-1, 352-2, 352-3, and 352-4 (hereinbelow, sometimes simply “insulating portions 352”) are provided between the setting thyristors S and the exit-surface protective films 351-1, 351-2, 351-3, and 351-4, respectively, as shown in FIGS. 3A and 3B. This prevents electrical contact between the exit-surface protective films 351 and the setting thyristors S.

The exit-surface protective films 351 may be made of an insulator, instead of metal. Such a configuration does not require the insulating portions 352. Examples of the insulator used in this exemplary embodiment include silicon dioxide (SiO₂), silicon nitride (Si₃N₄), polyimide, and benzocyclobutene (BCB). The insulator and the insulating portion 352 only need to exhibit an insulating property when used. So, besides the materials that always and only exhibit insulating properties, a semiconductor having a high resistance and exhibiting an insulating property against the external light, a current flowing through a VCSEL, or the like may be used.

The exit-surface protective films 351 only cover the inner surfaces of the openings δ and do not entirely cover the emitting parts, which are the bottom surfaces of the openings. By doing so, emission of light is not blocked, because the member covering the inner surface absorbs light. The insulating portions 352 are less likely to absorb light than the exit-surface protective films 351. Hence, the insulating portions 352 cover the inner surfaces, which correspond to the side surfaces of the openings δ. Also when the exit-surface protective films 351 are made of an insulator, the exit-surface protective films 351 do not entirely cover the emitting parts, which are the bottom surfaces of the openings δ, unlike the insulating portions 352.

In this exemplary embodiment, interlayer films 353 are provided at holes 301a between the islands 301. The interlayer films 353 are made of an insulator, which may be either the same as or different from the material of the insulating portion 352. The exit-surface protective films 351 and the interlayer films 353 may be made of either the same material or different materials. The exit-surface protective films 351 and the interlayer films 353 may be formed in either the same step or different steps.

In FIG. 3B, a portion of the n-cathode layer 88 of the drive thyristor DT is removed to expose the p-gate layer 87. On the exposed p-gate layer 87, a p-ohmic electrode 331 (FIG. 3B shows only the p-ohmic electrode 331-1) made of metal that easily forms ohmic contact with the p-gate layer 87 is provided. The wire 76 (see FIG. 4) connecting the p-ohmic electrode 331-1 and the n-ohmic electrode 322 on a region 312 of the connection diode Db1 provided in the island 302 is provided on the insulating layer 90.

In FIG. 3B, the lighting signal wire 74-1 connected to the n-ohmic electrode 321-1 is connected to n-ohmic electrodes of the other drive thyristors DT21 (DT/LD21), DT31 (DT/LD31), and DT41 (DT/LD41) similar to the n-ohmic electrodes 321-1.

FIG. 4 is an enlarged plan view of a drive thyristor DT/laser diode LD. Although the drive thyristor DT11/laser diode LD11 will be described here, the drive thyristor DT12/laser diode LD12, the drive thyristor DT13/laser diode LD13, and the drive thyristor DT14/laser diode LD14 arranged in the y direction also have the same configuration. So, a reference sign with “j” is also shown. The lighting signal wire 74-1 is indicated by a broken line so as to be distinguished from the others.

As shown in FIG. 4, the drive thyristor DT11/laser diode LD11 (drive thyristor DT1j/laser diode LD1j) is provided in the island 301-1 (island 301-j). The islands 301-1 (islands 301-j) have circular plan view and have circular emission ports y, through which light is emitted, at the center. The islands 301-1 (islands 301-j) does not need to have circular plan view and may have another shape, such as a quadrangular shape or a polygonal shape having more than four sides. The emission port γ may also have another shape.

A portion of the n-cathode layer 88 in the peripheral portion is removed to expose the p-gate layer 87. On the exposed p-gate layer 87, a p-ohmic electrode 331-1 (331-j) is provided. The p-ohmic electrode 331-1 (331-j) includes a contact via 331a-1 (331a-j) and a contact metal 331b-1 (331b-j). The contact metal 331b-1 (331b-j) of the p-ohmic electrode 331-1 (p-ohmic electrodes 331-j) is connected to the wire 76.

On the n-cathode layer 88, the n-ohmic electrode 321-1 (n-ohmic electrode 321-j) is provided in a horseshoe shape so as to surround the emission port γ. The n-ohmic electrode 321-1 (n-ohmic electrode 321-j) includes the contact via 321a-1 (321a-j) and the contact metal 321b-1 (321b-j). The contact metal 321b-1 (321b-j) of the n-ohmic electrode 321-1 is connected to the lighting signal wire 74-1. The lighting signal wire 74-1 has an opening δ at the portion corresponding to the light emission port γ.

Hence, the light emitted from the laser diode LD1j is not blocked by the lighting signal wire 74-1.

As shown in FIGS. 3A and 3B, the light emitted from the laser diodes LD1j is emitted via the drive thyristors DT1j. In another example, the drive thyristors DT1j located at positions where the light emitted from the laser diodes LD1j passes may be partially or entirely removed to reduce or eliminate the light absorbed in the drive thyristors DT1j. Alternatively, the laser diodes LD1j may emit light in the direction of the substrate 80 (back surface emission).

Although the drive thyristors DT1j and the laser diodes LD1j arranged in the y direction have been described above, the drive thyristors DT and the laser diodes LD arranged in the x direction also have this configuration.

FIG. 5 is a sectional view of the island 302 including the setting thyristor S1 and the connection diode Db1 and the island 303 including the transfer thyristor T1, the coupling diode D1, and the connection diode Da1. FIG. 5 is a sectional view taken along line V-V in FIG. 2. FIG. 5 shows, from the left side (the positive side in the y direction), the coupling diode D1, the transfer thyristor T1, the connection diode Da1, the setting thyristor S1, and the connection diode Dbi.

On the substrate 80 made of p-type GaAs are stacked the p-anode layer 81, the light-emitting layer 82, the n-cathode layer 83, the tunnel junction layer 84, the p-anode layer 85, the n-gate layer 86, the p-gate layer 87, and the n-cathode layer 88. That is, the structure of the semiconductor layer stack in the islands 302 and 303 is the same as that of the drive thyristor DT/laser diode LD shown in FIGS. 3A and 3B.

However, as shown in FIG. 5, the outer portions of the islands 302 and 303 are mesa-etched to the substrate 80. The portion between the islands 302 and 303 is mesa-etched to the p-anode layer 85. The p-anode layer 85 is connected to the substrate 80 (reference potential Vsub) by the wire 78. That is, in the islands 302 and 303, the p-anode layers 81, the light-emitting layers 82, and the n-cathode layers 83, serving as the laser diodes LD in the islands 301, are short-circuited by the wire 78 so as not to serve as the laser diodes LD. The wire 78 is in contact with the exposed side surfaces of the p-anode layer 81, the light-emitting layer 82, and the n-cathode layer 83. Because these layers are not used as the laser diode LD, the layers exposed to the side surfaces may be short-circuited. The wire 78, which connects the p-type substrate 80 and the p-anode layer 85, may be formed simultaneously with the p-ohmic electrode 331 and the like.

The p-anode layers 85 of the islands 304, 305, 306, and 307 (not shown in FIG. 5) are also connected to the p-anode layers 85 of the islands 302 and 303.

That is, as shown in FIG. 2, the substrate 80 includes a region 80B, where the semiconductor layer stack is mesa-etched to the substrate 80, and a region 80A, where the semiconductor layer stack is mesa-etched until the p-anode layer 85 is exposed. The region 80A includes the islands 302, 303, 304, 305, 306, and 307, and similar islands. The region 80B includes the islands 301-j and similar islands. In the region 80A, it is only necessary that the current blocking region R is formed in the p-anode layer 81. So, a portion of the p-anode layer 81 may remain. In the region 80B, it is only necessary that the p-anode layer 85 remains. So, the p-anode layer 85 may be partially etched in the thickness direction.

Next, the islands 302 and 303 will be described in detail.

In the island 302, the p-gate layer 87 is exposed except for regions 312 and 313 of the n-cathode layer 88. In the connection diode Db1, the region 312 of the n-cathode layer 88 serves as the cathode layer, and the n-ohmic electrode 322 provided on the region 312 serves as the cathode. In the connection diode Db1, the p-gate layer 87 serves as the anode layer and is connected to the gate layer 87 of the setting thyristor S1 beside the connection diode Db1. Alternatively, in the connection diode Db1, the p-ohmic electrode 332 provided on the p-gate layer 87 serves as the anode.

In the setting thyristor S1, the region 313 of the n-cathode layer 88 serves as the cathode layer, the p-anode layer 85 serves as the anode layer, and the p-gate layer 87 and the n-gate layer 86 provided therebetween serve as the p-gate layer and the n-gate layer, respectively. The p-anode layer 85 is connected to the substrate 80 (reference potential Vsub). The p-ohmic electrode 332 provided on the p-gate layer 87 serves as the gate.

In the island 303, the p-gate layer 87 is exposed except for regions 314, 315, and 316 of the n-cathode layer 88. In the connection diode Da1, the region 314 of the n-cathode layer 88 serves as the cathode layer, and an n-ohmic electrode 324 provided on the region 314 serves as the cathode. In the connection diode Da1, the p-gate layer 87 serves as the anode layer, and a p-ohmic electrode 333 (see FIG. 2) provided on the p-gate layer 87 serves as the anode. Similarly, in the coupling diode D1, the region 316 of the n-cathode layer 88 serves as the cathode layer, and an n-ohmic electrode 326 provided on the region 316 serves as the cathode. In the coupling diode D1, the p-gate layer 87 serves as the anode layer and is connected to the p-gate layer 87 of the transfer thyristor T1 beside the coupling diode D1. Alternatively, in the coupling diode D1, the p-ohmic electrode 333 (see FIG. 2) provided on the p-gate layer 87 serve as the anode.

In the transfer thyristor T1, the region 315 of the n-cathode layer 88 serves as the cathode layer, the p-anode layer 85 serves as the anode layer, and the p-gate layer 87 and the n-gate layer 86 provided therebetween serve as the p-gate layer and the n-gate layer, respectively. The p-anode layer 85 is connected to the substrate 80 (reference potential Vsub). The p-ohmic electrode 333 (see FIG. 2) provided on the p-gate layer 87 serves as the gate.

Referring back to FIG. 2, the islands 304, 305, 306, and 307 will be described.

In the island 304, the n-cathode layer 88 is removed to expose the p-gate layer 87. In the resistor Rg1, the p-gate layer 87 between p-ohmic electrodes 334 and 335 provided on the exposed p-gate layer 87 serves as the resistor (see FIG. 2).

In the island 305, the p-gate layer 87 is exposed except for a region 317 of the n-cathode layer 88. In the start diode SD, the region 317 of the n-cathode layer 88 serves as the cathode layer, and an n-ohmic electrode 327 provided on the region 317 serves as the cathode. A p-ohmic electrode 336 provided on the p-gate layer 87 serves as the anode.

In the islands 306 and 307, the n-cathode layer 88 is removed to expose the p-gate layer 87, similarly to the island 304. Similarly to the resistor Rg1, the p-gate layers 87 between pairs of p-ohmic electrodes (no reference signs added) provided on the p-gate layers 87 serve as the current limiting resistors R1 and R2.

Referring to FIG. 2, the connection relationship among the islands 301 to 307 will be described. Because the same connection relationship applies to the islands provided parallel to the islands 301 to 304, the description thereof will be omitted.

The power supply wire 71 extending from the Vgk terminal is connected to the p-ohmic electrode 335 of the island 304 provided with the resistor Rg1.

The transfer signal wire 72 extending from the el terminal is connected to an n-ohmic electrode 325 of the transfer thyristor T1 provided in the island 303 via the current limiting resistor R1 provided in the island 306. The transfer signal wire 72 is connected to the odd-numbered transfer thyristors T provided in the islands similar to the island 303.

The transfer signal wire 73 extending from the φ2 terminal is connected to n-ohmic electrodes (no reference signs added) of the even-numbered transfer thyristors T provided in the islands similar to the island 303 via the current limiting resistor R2 provided in the island 307. The transfer signal wire 73 is connected to the p-ohmic electrode 336 of the start diode SD.

The lighting signal wires 74-j are connected to the n-ohmic electrodes 321-j of the drive thyristors DT1j/laser diodes LD1j (DT/LD1j) provided in the islands 301-j.

The setting signal wire 75 is connected to the n-ohmic electrode 323 of the setting thyristor S1 provided in the island 302.

The p-ohmic electrodes 331-j (see FIG. 4) of the drive thyristors DT1j/laser diodes LD1j (DT/LD1j) in the islands 301-j and the n-ohmic electrode 322 of the connection diode Db1 in the island 302 are connected by the wire 76.

The p-ohmic electrode 332, which is the gate electrode Gs1 of the setting thyristor S1 in the island 302, and the n-ohmic electrode 324 of the connection diode Da1 in the island 303 are connected to each other by the wire 77.

The p-ohmic electrode 333 in the island 303, the p-ohmic electrode 334 of the resistor Rg1 in the island 304, and the n-ohmic electrode 327 of the start diode SD are connected to one another by the wire 79. The n-ohmic electrode 326 of the coupling diode D1 in the island 303 is connected to the gate Gt2 of the transfer thyristor T2 provided in an island adjoining and similar to the island 303 by a wire similar to the wire 79.

Portions between the islands 302, 303, 304, 305, 306, and 307 are mesa-etched until the p-anode layer 85 is exposed, as described above. The p-anode layer 85 is connected to the substrate 80 by the wire 78. In FIG. 2, the wire 78 is shown on the right side, although the position thereof is different from that in FIG. 5. The wire 78 connects the regions 80A and 80B of the substrate 80.

The form of the exit-surface protective film 351 is not limited to the form described with reference to FIGS. 3A, 3B, and 4. Another form of the exit-surface protective film 351 will be described below.

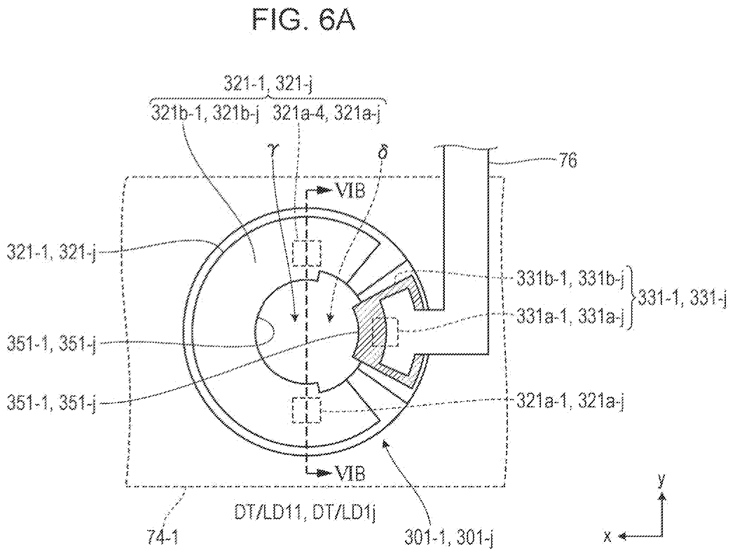

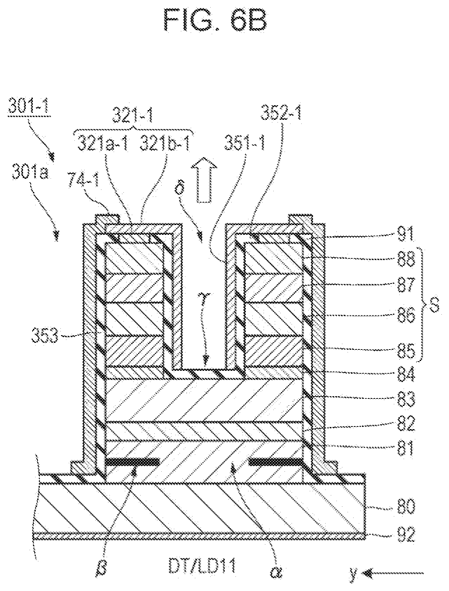

FIGS. 6A to 8B show a first example of another form of the exit-surface protective film 351.

In this example, the exit-surface protective film 351 covers a part of the inner surface of the opening δ.

FIGS. 6A and 6B show the case where the exit-surface protective film 351 covers a smaller area of the cylindrical inner surface of the opening δ when the inner surface is viewed from above.

Although the island 301-1 is shown as an example, the other islands, 301-2, 301-3, 301-4, and the like, also have the same configuration as the island 301-1.

FIG. 6A shows the island 301-1 viewed from the same direction as in FIG. 4. FIG. 6B is a sectional view taken along line VIB-VIB in FIG. 6A.

In this case, the width of the exit-surface protective film 351 extending from the n-ohmic electrode 321 to the inner surface of the opening δ is smaller than that shown in FIG. 3. By providing the exit-surface protective film 351 only at a portion, for example, where the external light is likely to enter as in this case, the above-described malfunction is suppressed, without covering the entire inner surface of the opening δ.

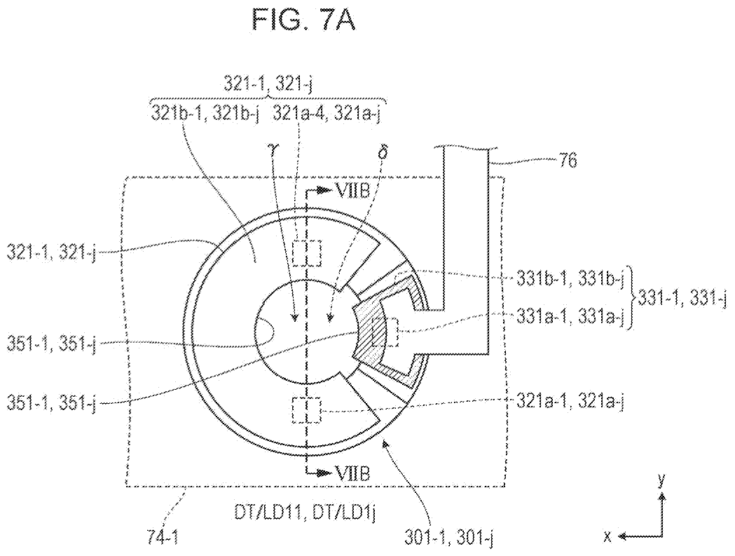

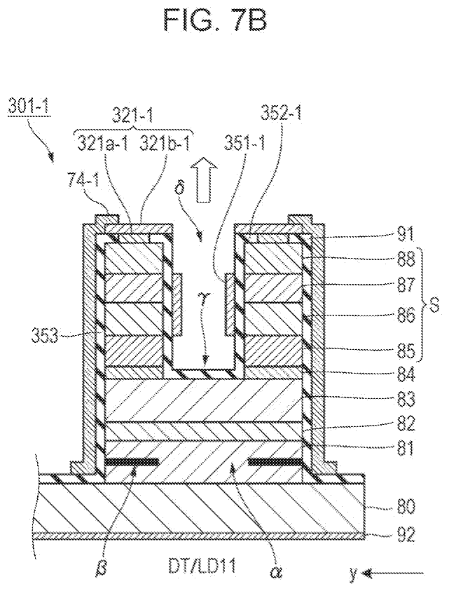

FIGS. 7A and 7B show a case where the exit-surface protective film 351 covers the gate layer of the setting thyristor S.

FIG. 7A shows the island 301-1 viewed from the same direction as in FIG. 4. FIG. 7B is a sectional view taken along line VIIB-VIIB in FIG. 7A.

In this case, the n-gate layer 86 and the p-gate layer 87 are covered. The n-gate layer 86 and the p-gate layer 87, which are likely to cause malfunction, are covered. As in this case, the above-described malfunction is suppressed without covering the entire inner surface of the opening δ.

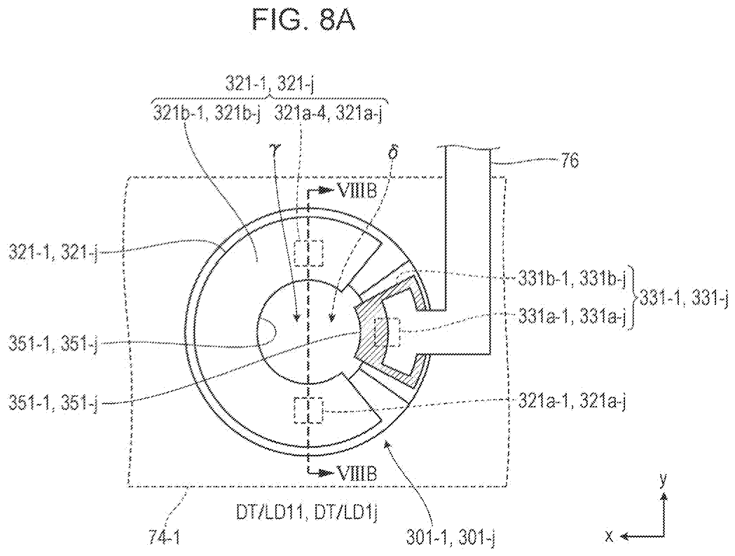

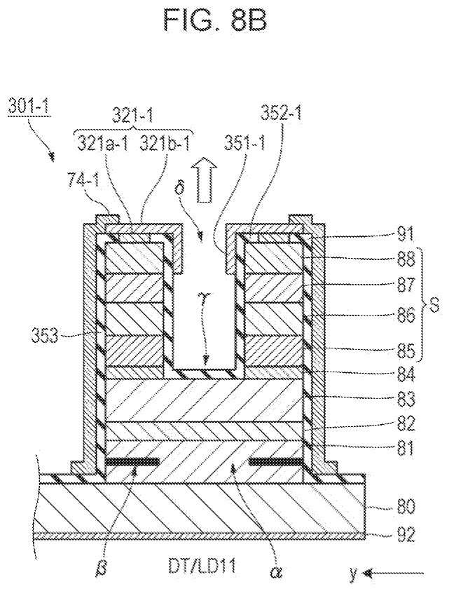

FIGS. 8A and 8B show a case where the exit-surface protective film 351 covers the n-cathode layer 88 of the setting thyristor S.

FIG. 8A shows the island 301-1 viewed from the same direction as in FIG. 4. FIG. 8B is a sectional view taken along line VIIIB-VIIIB in FIG. 8A.

This form is adopted when the n-cathode layer 88 is likely to absorb light, such as the external light, and the other layers are less likely to absorb the light. In this case, the exit-surface protective film 351 covers the n-cathode layer 88, which is likely to cause malfunction, and does not cover the other layers, which are less likely to cause malfunction. As in this case, the above-described malfunction is suppressed without covering the entire inner surface of the opening δ.

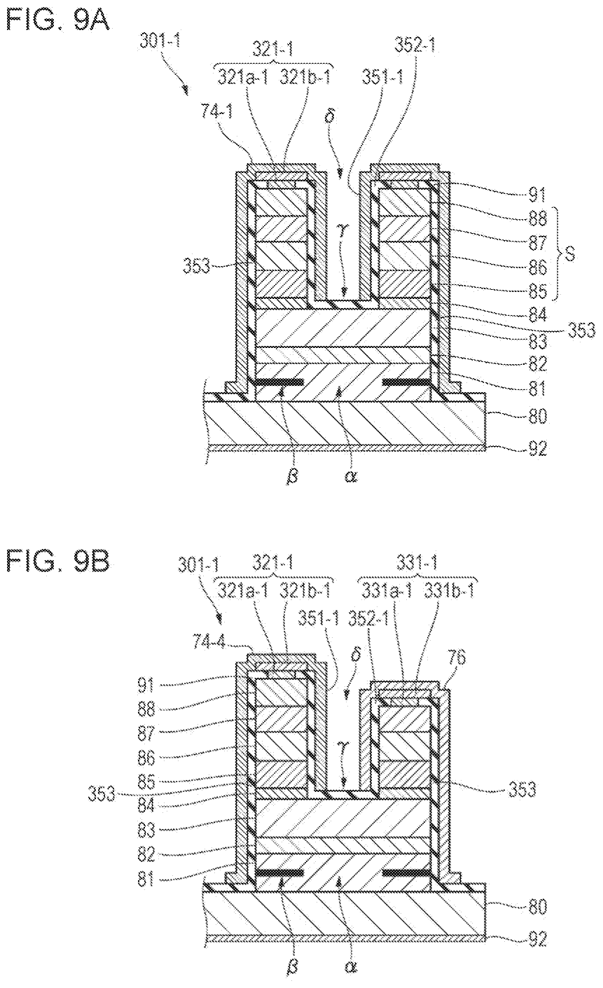

FIGS. 9A and 9B show a second example of the other form of the exit-surface protective film 351.

In FIGS. 9A and 9B, the configuration of the exit-surface protective film 351-1 is different from that in FIG. 3. Also in this exemplary embodiment, the exit-surface protective film 351-1 covers the inner surface of the opening δ. In this exemplary embodiment, the lighting signal wire 74-1, which is a current supply wire electrically connected to the setting thyristor S, extends to the inner surface of the opening S to form the exit-surface protective film 351-1. In other words, the exit-surface protective film 351-1 provided on the inner surface of the opening S is the lighting signal wire 74-1 extending to the inner surface of the opening δ. In still other words, the exit-surface protective film 351-1 is formed integrally with the lighting signal wire 74-1.

When the exit-surface protective film 351-1 is made of metal, the insulating portion 352-1 and the interlayer film 353 are provided between the setting thyristor S and the exit-surface protective film 351-1, as shown in FIGS. 9A and 9B. This prevents electrical contact between the exit-surface protective film 351-1 and the setting thyristor S.

When an insulator is used as the exit-surface protective film 351 instead of metal, the insulating portion 352 and the interlayer film 353 are unnecessary.

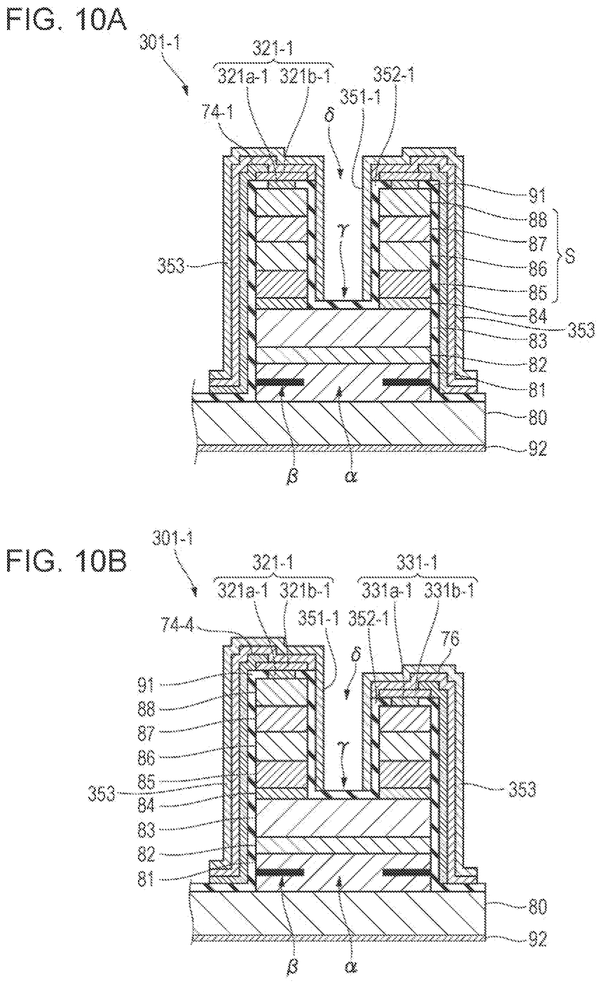

FIGS. 10A and 10B show a third example of the other form of the exit-surface protective film 351.

In FIGS. 10A and 10B, the configuration of the exit-surface protective film 351-1 is different from that in FIG. 3, as in FIGS. 9A and 9B. Also in this exemplary embodiment, the exit-surface protective film 351-1 covers the inner surface of the opening δ. In this exemplary embodiment, the exit-surface protective film 351-1 is formed without being electrically connected to the n-ohmic electrode 321-1, the p-ohmic electrode 331-1, or the lighting signal wire 74-1. In this exemplary embodiment, the interlayer film 353 is located on the outer side, and the interlayer film 353 extends to the inner surface of the opening S to form the exit-surface protective film 351-1. When the exit-surface protective film 351-1 is made of metal, the interlayer film 353 is made of the same metal. In other words, the exit-surface protective film 351-1 provided on the inner surface of the opening δ is the interlayer film 353 extending to the inner surface of the opening δ. In still other words, the exit-surface protective film 351-1 is formed integrally with the interlayer film 353.

When the exit-surface protective film 351-1 is made of metal, the insulating portion 352-1 is provided between the exit-surface protective film 351-1 and the setting thyristor S, the n-ohmic electrode 321-1, the lighting signal wire 74-1. In other words, the exit-surface protective film 351 covers the setting thyristor S, the n-ohmic electrode 321-1, and the lighting signal wire 74-1 with the insulating portion 352-1 therebetween. This prevents electrical contact between the exit-surface protective film 351-1 and the setting thyristor S, as well as electrical contact between the exit-surface protective film 351-1 and the lighting signal wire 74-1.

When an insulator is used as the exit-surface protective film 351-1 instead of metal, the insulating portion 352-1 is unnecessary.

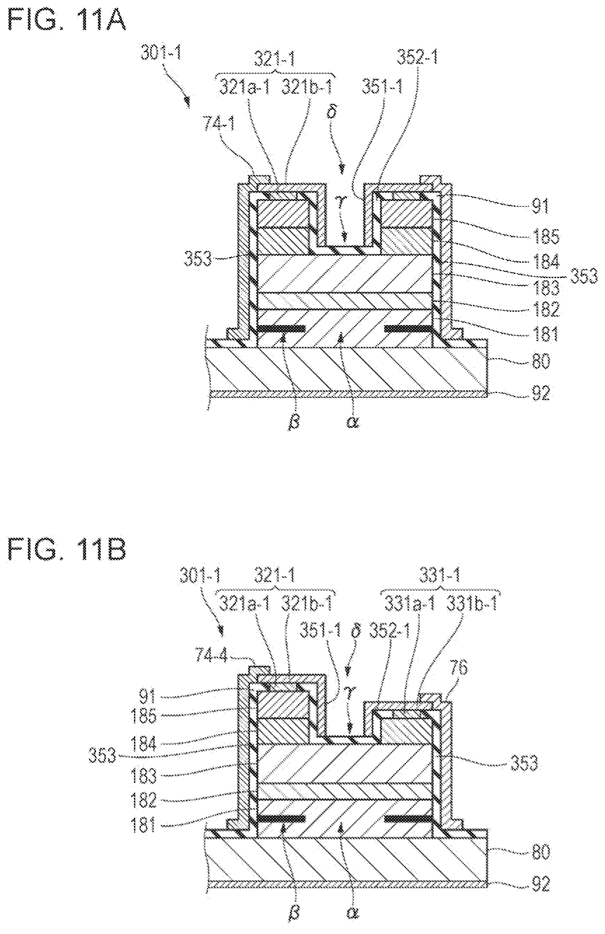

FIGS. 11A and 11B show a fourth example of the other form of the exit-surface protective film 351.

In FIGS. 11A and 11B, the configuration of the exit-surface protective film 351 is different from that in FIG. 3, as in FIGS. 9A to 10B. In this exemplary embodiment, the island 301-1 includes, in this order from below, a p-anode layer 181, an n-gate layer 182, a light-emitting layer 183, a p-gate layer 184, and an n-cathode layer 185.

The island 301-1 has a thyristor structure including the p-anode layer 181, the n-gate layer 182, the p-gate layer 184, and the n-cathode layer 185. In other words, the island 301-1 has a stacked structure including the thyristor and the light-emitting layer 183, which is provided between the layers constituting the thyristor and emits light.

Also in this exemplary embodiment, the exit-surface protective film 351-1 covers the inner surface of the opening δ. The configuration of the electrode and the wire on the upper side of the island 301-1 is the same as that in FIG. 3.

Stacked Structure of Drive Thyristor DT and Laser Diode LD Next, the stacked structure of the drive thyristors DT1j and the laser diodes LD1j in the islands 301-j (j=1 to 4) shown in FIGS. 3A and 3B will be described. Here, the stacked structure of the drive thyristor DT1j and the laser diode LD1j will be described using the drive thyristor DT11 and the laser diode LD11 as an example. In the stacked structure of the drive thyristor DT11 and the laser diode LD11, the reference potential Vsub is applied to the back-surface electrode 92 of the substrate 80, and the lighting signal φI1 is supplied to the lighting signal wire 74-1 connected to the n-ohmic electrode 321-1 provided on the n-cathode layer 88. A gate voltage is applied to the p-ohmic electrode 331-1, which is a gate Gd11, provided on the p-gate layer 87 shown in FIG. 3B.

Hereinbelow, the drive thyristor DT11 will be written as the drive thyristor DT, the laser diode LD11 will be written as the laser diode LD, the n-ohmic electrode 321-1 will be written as the n-ohmic electrode 321, the lighting signal φI1 will be written as the lighting signal φI, and the gate voltage applied to the gate Gd11 will be written as the potential of the gate Gd.

The drive thyristor DT is stacked on the laser diode LD with the tunnel junction layer 84 therebetween, and the drive thyristor DT and the laser diode LD are connected in series.

First, the tunnel junction layer 84 will be described.

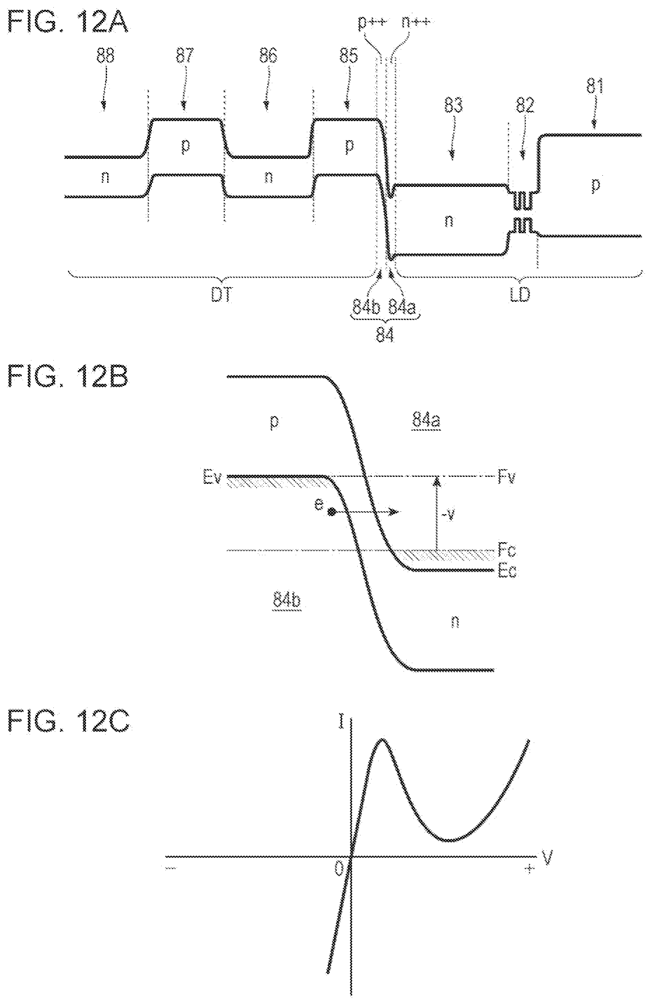

FIGS. 12A to 12C show a stacked structure of the laser diode LD and the drive thyristor DT in more detail. FIG. 12A schematically shows the energy band of the stacked structure of the laser diode LD and the drive thyristor DT, FIG. 12B shows the energy band of the tunnel junction layer 84 in a reverse bias state, and FIG. 12C shows a current-voltage characteristic of the tunnel junction layer 84.

When a voltage that forward-biases the laser diode LD and the driving thyristor DT is applied between the lighting signal φI applied to the n-ohmic electrode 321 and the reference potential Vsub of the back-surface electrode 92, as shown in the energy band diagram of FIG. 12A, the junction between an n⁺⁺layer 84a and a p⁺⁺layer 84b constituting the tunnel junction layer 84 is reverse-biased.

The tunnel junction layer 84 is a junction of the n⁺⁺layer 84a doped with a high concentration of an n-type impurity and the p⁺⁺layer 84b doped with a high concentration of a p-type impurity. Hence, the width of the depletion region is narrow, and when forward biased, electrons tunnel from the conduction band on the n⁺⁺layer 84a side to the valence band on the p⁺⁺layer 84b side. At this time, negative resistance characteristics appear (see the forward bias side (+V) in FIG. 12C).

Meanwhile, as shown in FIG. 12B, when the tunnel junction layer 84 is reverse-biased (−V), the potential Ev of the valence band on the p⁺⁺layer 84b side becomes higher than the potential Ec of the conduction band on the n⁺⁺layer 84a side. Thus, electrons tunnel from the valence band on the p⁺⁺layer 84b side to the conduction band on the n⁺⁺layer 84a side. As the reverse bias voltage (−V) increases, electrons tunnel more easily. That is, as shown on the reverse bias side (−V) in FIG. 12C, in the tunnel junction layer 84 (tunnel junction), the larger the reverse bias is, the more easily the current flows.

Hence, as shown in FIG. 12A, when the drive thyristor DT is turned on, a current flows between the laser diode LD and the drive thyristor DT even through the tunnel junction layer 84 is reverse-biased.

Instead of the tunnel junction layer 84, a III-V compound layer that has metallic conductivity and that is epitaxially grown to form a III-V compound semiconductor layer may be used. The band gap energy of InNAs, which is an example of the material of the metallically conductive III-V compound layer, is negative when, for example, the composition ratio x of InN is in the range of about 0.1 to 0.8. The band gap energy of InNSb is negative when, for example, the composition ratio x of InN is in the range of about 0.2 to 0.75. The band gap energy being negative means that there is no band gap. Hence, the same conductive property (conduction property) as metal is exhibited. The metallic conductive property (conductivity) is a property in which a current flows if there is a potential gradient, as in metal.

The lattice constants of the III-V compounds (semiconductors), such as GaAs and InP, are in the range of 5.6 Å to 5.9 Å. These lattice constants are close to the lattice constant of Si (about 5.43 Å) and the lattice constant of Ge (about 5.66 Å).

Meanwhile, the lattice constant of InN, which is also a III-V compound, in the zincblende structure is about 5.0 Å, and the lattice constant of InAs is about 6.06 Å. Hence, the lattice constant of InNAs, which is a compound of InN and InAs, can be a value close to 5.6 Å to 5.9 Å, which is the lattice constant of GaAs and the like.

The lattice constant of InSb, which is a III-V compound, is about 6.48 Å. Because the lattice constant of InN is about 5.0 Å, the lattice constant of InNSb, which is a compound of InSb and InN, can be a value close to 5.6 Å to 5.9 Å, which is the lattice constant of GaAs and the like.

InNAs and InNSb can be epitaxially grown monolithically on a layer of a III-V compound (semiconductor), such as GaAs.

Furthermore, a layer of a III-V compound (semiconductor), such as GaAs, can be monolithically stacked on the layer of InNAs or InNSb by epitaxial growth.

Accordingly, by connecting in series and stacking the laser diode LD and the drive thyristor DT via a metallically conductive III-V compound layer instead of the tunnel junction layer 84, it is possible to prevent the n-cathode layer 83 of the laser diode LD and the p-anode layer 85 of the drive thyristor DT from being reverse-biased.

### Basic Operation of Drive Thyristor DT and Laser Diode LD

Next, the basic operation of the drive thyristor DT and the laser diode LD will be described.

The laser diode LD has a turn-on voltage of 1.5 V. This means that the laser diode LD is lit (emits light) when a voltage of 1.5 V or more is applied between the anode and the cathode of the laser diode LD.

In the structure in which the drive thyristor DT and the laser diode LD are connected in series, the p-anode layer 81 in the laser diode LD and the current blocking region 3, serving as the current confinement layer in the p-anode layer 81, have the major series resistance component. Hence, the voltage between the anode and the gate of the drive thyristor DT in the on state is higher than the voltage of the lighting signal φI by 0.8 V (holding voltage).

The lighting signal φI has a potential of 0 V, −3.1 V, −2.5 V, or a negative potential with an absolute value greater than −3.1 V (−3.5 V here). In the lighting signal PI, 0 V is a potential for turning off the laser diode LD, −3.1 V is a potential for turning on the laser diode LD, −2.5 V is a potential for maintaining the laser diode LD in the on state, and −3.5 V is a potential for lighting the laser diode LD in the on state with a predetermined light intensity.

When the laser diode LD is turned on, the lighting signal φI is set to −3.1 V. At this time, when a voltage of −1.5 V is applied to the gate Gd, the threshold of the drive thyristor is −3 V, which is obtained by subtracting the forward potential Vd (1.5 V) of the pn junction from the potential (−1.5 V) of the gate Gd. Because the lighting signal φI at this time is −3.1 V, the laser diode LD is turned on. Specifically, the laser diode LD performs laser oscillation and is lit (emits light). Because the voltage (holding voltage) applied to the drive thyristor DT in the on state is 0.8 V, a voltage of 2.3 V is applied to the laser diode LD.

Next, the lighting signal φI is shifted from −3.1 V to −2.5 V. Because the holding voltage of the drive thyristor DT in the on state is 0.8 V, a voltage of 1.7 V is applied to the laser diode LD. Because 1.7 V is higher than or equal to 1.5 V, which is the turn-on voltage of the laser diode LD, the laser diode LD continues to be lit (emit light).

When the lighting signal φI is set to −3.5 V, because the holding voltage of the drive thyristor DT in the on state is 0.8 V, a voltage of 2.7 V is applied to the laser diode LD. That is, the highest voltage is applied to the laser diode LD, maximizing the light intensity of the laser diode LD (making the laser diode LD emit strong light).

When the lighting signal φI is set to 0 V, a voltage of 0 V is applied to the series connection of the drive thyristor DT and the laser diode LD, turning off the drive thyristor DT, and turning off the laser diode LD.

The operation of the light-emitting device 10 will be described in detail below.

When the drive thyristor DT is turned off, electric charges remain between the anode of the drive thyristor DT and the cathode of the laser diode LD. However, the voltage between the anode of the drive thyristor DT and the cathode of the laser diode LD is a voltage (−1.5 V) that is lower than the reference potential Vsub (0 V) by the turn-on voltage (1.5 V) of the laser diode LD. Hence, in the off state, the anode and the gate of the drive thyristor are electrically disconnected, and thus, the switching voltage is not affected. Thus, the drive thyristor DT is likely to be stably operated.

Layer Structure of Light-Emitting Unit 100 and Method for Manufacturing Light-Emitting Unit 100

Now, a layer structure of the light-emitting unit 100 and a method for manufacturing the light-emitting unit 100 will be described with reference to FIGS. 3A and 3B.

First, on the p-type substrate 80 are epitaxially grown the p-anode (DBR) layer 81, the light-emitting layer 82, the n-cathode (DBR) layer 83, the tunnel junction layer 84, the p-anode layer 85, the n-gate layer 86, the p-gate layer 87, and the n-cathode layer 88 in this order to form a semiconductor stack (layer forming step). Although the substrate 80 made of p-type GaAs will be described as an example, the substrate 80 may be made of n-type GaAs or intrinsic (i)-type GaAs without being doped.

The DBR layer includes a combination of a high Al composition low-refractive-index layer made of, for example, Al_{0.9}Ga_{0.1}As, and a low Al composition high-refractive-index layer made of, for example, Al_{0.2}Ga_{0.8}As. The film thickness (optical path length) of each of the low-refractive-index layer and the high-refractive-index layer is set to, for example, 0.25 (¼) of the center wavelength. The composition ratio of Al in the low-refractive-index layer and the high-refractive-index layer may be changed in the range of 0 to 1.

The p-anode (DBR) layer 81 is formed by stacking a lower p-anode (DBR) layer 81a, a current confinement layer 81b, and an upper p-anode (DBR) layer 81c in this order. The lower p-anode (DBR) layer 81a and the upper p-anode (DBR) layer 81c have an impurity concentration of 1×10¹⁸/cm³, for example. The current confinement layer 81b is made of, for example, AlAs or p-type AlGaAs in which Al has a high impurity concentration. Any material that has a high electrical resistance and narrows the current path due to Al being oxidized to Al₂O₃ may be used.

The thickness (optical path length) of the current confinement layer 81b in the p-anode (DBR) layer 81 is determined depending on the structure employed. When the light extraction efficiency and the process reproducibility are prioritized, the thickness of the current confinement layer 81b is desirably set to an integral multiple of the film thickness (optical path length) of the low-refractive-index layer and the high-refractive-index layer constituting the DBR layer, and thus is set to, for example, 0.75 (¾) of the center wavelength. In the case of an odd multiple, the current confinement layer 81b is desirably sandwiched between high-refractive-index layers. In the case of an even multiple, the current confinement layer 81b is desirably sandwiched between a high-refractive-index layer and a low-refractive-index layer. That is, the current confinement layer 81b is provided to suppress disturbance of the periodicity of the refractive index caused by the DBR layer. In contrast, when it is intended to reduce the influence (refractive index and strain) of the oxidized portion, it is desirable that the current confinement layer 81b have a thickness of several tens of nm and be inserted at a node of standing waves generated in the DBR layer.

The light-emitting layer 82 has a quantum well structure in which well layers and barrier layers are alternately stacked. The well layers are made of, for example, GaAs, AlGaAs, InGaAs, GaAsP, AlGaInP, GaInAsP, or GaInP, and the barrier layers are made of AlGaAs, GaAs, GaInP, or GaInAsP. The light-emitting layer 82 may alternatively have a quantum wire structure or a quantum dot structure.

The n-cathode (DBR) layer 83 has an impurity concentration of 1×10¹⁸/cm³, for example.

The tunnel junction layer 84 is formed of a junction (see FIG. 12A described below) of the n⁺⁺layer 84a doped with a high concentration of an n-type impurity and the p⁺⁺layer 84b doped with a high concentration of an n-type impurity. The impurity concentration of the n⁺⁺layer 84a and the p⁺⁺layer 84b is high and is, for example, 1×10²⁰/cm³. The impurity concentration of a normal junction is in the order of 10¹⁷ to 10¹⁸/cm³. Example combinations of the n⁺⁺layer 84a and the p⁺⁺layer 84b (hereinbelow, n⁺⁺layer 84a/p⁺⁺layer 84b) include n⁺⁺GaInP/p⁺⁺GaAs, n⁺⁺GaInP/p⁺⁺AlGaAs, n⁺⁺GaAs/p⁺⁺GaAs, n⁺⁺AlGaAs/p⁺⁺AlGaAs, n⁺⁺InGaAs/p⁺⁺InGaAs, n⁺⁺GaInAsP/p⁺⁺GaInAsP, and n⁺⁺GaAsSb/p⁺⁺GaAsSb. These combinations may be mutually changed.

The p-anode layer 85 is made of, for example, p-type Al_{0.9}GaAs having an impurity concentration of 1×10¹⁸/cm³. The Al composition may be changed in the range of 0 to 1.

The n-gate layer 86 is made of, for example, n-type Al_{0.9}GaAs having an impurity concentration of 1×10¹⁷/cm³. The Al composition may be changed in the range of 0 to 1.

The p-gate layer 87 is made of, for example, p-type Al_{0.9}GaAs having an impurity concentration of 1×10¹⁷/cm³. The Al composition may be changed in the range of 0 to 1.

The n-cathode layer 88 is made of, for example, n-type Al_{0.9}GaAs having an impurity concentration of 1×10¹⁸/cm³. The Al composition may be changed in the range of 0 to 1.

These semiconductor layers are stacked by a metal organic chemical vapor deposition (MOCVD) method, a molecular beam epitaxy (MBE) method, or the like to form a semiconductor stack.

Next, the n-cathode layer 88, the p-gate layer 87, the n-gate layer 86, the p-anode layer 85, the tunnel junction layer 84, the n-cathode (DBR) layer 83, the light-emitting layer 82, and the p-anode (DBR) layer 81 are sequentially etched to form separate stacked structures, such as the islands 301 and 302. At the same time, the holes 301a in the islands 301 are formed (hole forming step). This etching may be either wet etching using a sulfuric acid-based etchant (the ratio of sulfuric acid to hydrogen peroxide solution and water is 1:10:300 by weight) or anisotropic dry etching (RIE) using, for example, boron chloride. This etching for forming separate stacked structures is sometimes called mesa etching or post etching.

Next, the n-cathode layer 88, the p-gate layer 87, the n-gate layer 86, the p-anode layer 85, and the tunnel junction layer 84 are sequentially etched to form the opening δ at the emission port γ (opening forming step).

Next, the current confinement layer 81b, whose side surface is exposed at the edge and hole 301a of each stacked structure, is oxidized from the side surface to form the current blocking region R (current-confinement-layer forming step). The current confinement layer 81b is oxidized by oxidizing Al in the current confinement layer 81b, which is made of AlAs, AlGaAs, or the like, by steam oxidation at 300 to 400° C., for example. At this time, oxidation proceeds from the exposed side surfaces, forming the current blocking regions R of Al₂O₃, which is an oxide of Al. The non-oxidized portion of the current confinement layer 81b serves as a current passing portion α.

Next, the n-cathode layer 88 is etched to expose the p-gate layer 87 (gate-layer exposing step). This etching may be either wet etching using a sulfuric acid-based etchant (the ratio of sulfuric acid to hydrogen peroxide solution and water is 1:10:300 by weight) or anisotropic dry etching using, for example, boron chloride. Then, p-ohmic electrodes (p-ohmic electrodes 331, 332, and the like) are formed on the p-gate layer 87. The p-ohmic electrodes are made of, for example, Au containing Zn (AuZn) that easily forms an ohmic contact with a p-type semiconductor layer, such as the p-gate layer 87. The p-ohmic electrodes (p-ohmic electrodes 331, 332, and the like) are formed by, for example, a lift-off method.

Next, the insulating portions 352 and the exit-surface protective films 351 are formed in the openings δ. Specifically, the upper part of the n-cathode layer 88, the p-gate layer 87, the n-gate layer 86, and the p-anode layer 85, which constitute the thyristor, and the inner surface of the opening δ formed in the opening forming step are covered with the exit-surface protective film 351, which absorbs light (covering step).

When metal is used as the exit-surface protective films 351, the exit-surface protective films 351 can be formed by sputtering, for example. Specifically, argon ions are caused to collide with a target made of a metal for forming the exit-surface protective film 351 in a vacuum state, and metal atoms emitted thereby are caused to adhere to the inner surface of the opening δ.

Next, the n-ohmic electrodes 321, 323, 324 and the like are formed on the n-cathode layer 88 (electrode forming step). The n-ohmic electrodes (n-ohmic electrode 321, 323, 324, and the like) are made of, for example, Au containing Ge (AuGe) that easily forms an ohmic contact with an n-type semiconductor layer, such as the n-cathode layer 88. The n-ohmic electrodes (n-ohmic electrode 321, 323, 324, and the like) are formed by, for example, a lift-off method.

Then, the wires (the power supply wire 71, the transfer signal wires 72 and 73, the setting signal wire 75, and the like) for connecting the n-ohmic electrodes (the n-ohmic electrodes 321, 323, 324, and the like) and the p-ohmic electrodes (the p-ohmic electrodes 331, 332, and the like), and the back-surface electrode 92 are formed (wire forming step). The wires and the back-surface electrode 92 are made of Al, Au, or the like.

This way, the light-emitting unit 100 is manufactured.

The substrate 80 may be a semiconductor substrate made of InP, GaN, InAs, or other III-V or II-VI materials, or may be made of sapphire, Si, Ge, or the like. When the substrate is changed, a material having a lattice constant that substantially matches the lattice constant of the substrate (including the strain structure, the strain relaxation layer, and the metamorphic growth) is used as the material of the semiconductor layer that is monolithically stacked on the substrate. For example, InAs, InAsSb, GaInAsSb, or the like is used on an InAs substrate, InP, InGaAsP, or the like is used on an InP substrate, GaN, AlGaN, or InGaN is used on a GaN or sapphire substrate, and Si, SiGe, GaP, or the like is used on a Si substrate. When the semiconductor layer is bonded to another support substrate after crystal growth, the lattice of the semiconductor material does not need to substantially match that of the support substrate.

In the method for manufacturing the light-emitting unit 100, the order of the steps is not limited to the order described above.

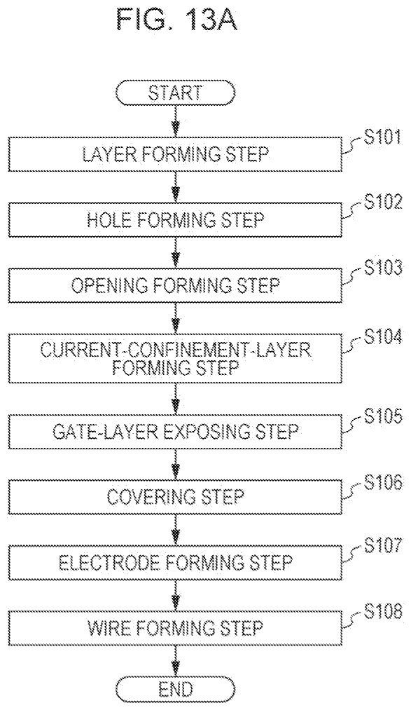

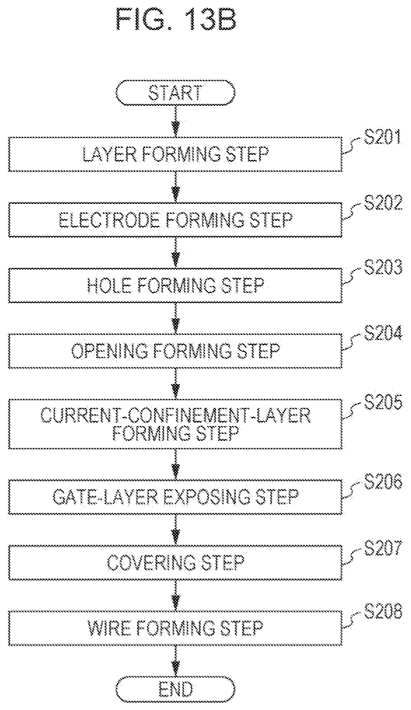

FIGS. 13A and 1B are flowcharts showing the orders of the steps in the method for manufacturing the light-emitting unit 100.

FIG. 13A is a flowchart showing the steps in the above-described order. The order of the steps is as follows: the layer forming step (S101), the hole forming step (S102), the opening forming step (S103), the current-confinement-layer forming step (S104), the gate-layer exposing step (S105), the covering step (S106), the electrode forming step (S107), and the wire forming step (S108). In this case, the electrodes are formed after the holes 301a and the openings δ are formed. This produces the structures shown in FIGS. 3A, 3B, 4, 6A, 6B, 7A, 7B, 8A, 8B, 9A, 9B, 11A, and 11B.

In the flowchart in FIG. 13B, the order of the steps is as follows: the layer forming step (S201), the electrode forming step (S202), the hole forming step (S203), the opening forming step (S204), the current-confinement-layer forming step (S205), the gate-layer exposing step (S206), the covering step (S207), and the wire forming step (S208). In FIG. 13B, the electrode forming step, which is S107 in FIG. 13A, occurs upstream, i.e., S202, in the process. That is, the electrodes are formed in an earlier step, not a later step. In this order, the electrodes are formed on the upper side of the semiconductor stack, and then the holes 301a and the like are formed. With this order, the electrodes can be formed on the upper side of the semiconductor stack having a smoother surface. In contrast, with the order in FIG. 13A, the upper surface of the semiconductor stack may be roughened when the holes 301a and the like are formed. Furthermore, it is possible to cover the upper side of the electrodes with the exit-surface protective films 351, and thus to produce the structure shown in FIG. 10.

### Operation of Light-Emitting Device 10

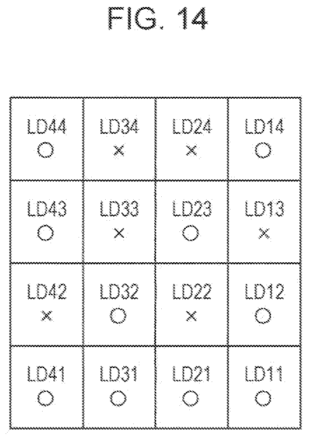

FIG. 14 shows an example control of lighting and non-lighting of the laser diodes LD in the light-emitting device 10. An example case described with reference to FIGS. 1 and 2, in which the laser diodes LD are arranged in a four by four matrix, will be described. In FIG. 14, the laser diodes LD to be lit (emit light) are indicated by “∘”, and the laser diode LD to be turned off are indicated by “x”. In this example, the laser diodes LD11, LD12, LD14, LD21, LD23, LD31, LD32, LD41, LD43, and LD44 are to be lit (emit light), and the laser diodes LD13, LD22, LD24, LD33, LD34, and LD42 are to be turned off.

When the light-emitting device 10 is viewed, a state (image) in which the portions with “∘” in FIG. 14 are turned on is viewed. The state in FIG. 14 corresponds to the states in FIGS. 1 and 2.

### Timing Chart

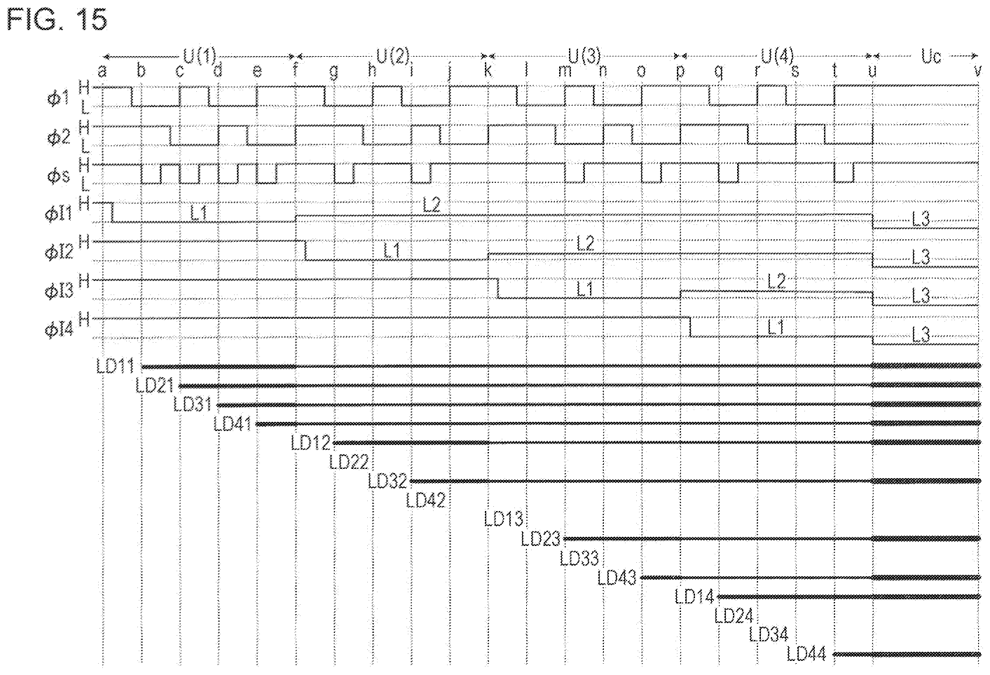

FIG. 15 is a timing chart for driving the light-emitting device 10. The light-emitting device 10 includes the laser diodes LD arranged in a four by four matrix, which are controlled to be in a lighting state and a non-lighting state as shown in FIG. 14. In FIG. 15, it is assumed that the time passes in the alphabetical order (a, b, c). The timing chart in FIG. 15 includes setting periods U(1) to U(4), in which it is determined whether the laser diodes LD are set to lighting or non-lighting, and a lighting maintaining period Uc, in which the laser diodes LD set to lighting are kept lit in parallel.

The period from time a to f corresponds to the setting period U(1) for the laser diodes LD11, LD21, LD31 and L41, the period from time f to k corresponds to the setting period U(2) for the laser diodes LD12, LD22, LD32 and L42, the period from time k to p corresponds to the setting period U(3) for the laser diodes LD13, LD23, LD33, and L43, and the period from time p to u corresponds to the setting period U(4) for the laser diodes LD14, LD24, LD34, and L44. The period from time u to v corresponds to the lighting maintaining period Uc, in which the laser diodes LD set to lighting are kept lit in parallel.

Assuming that the setting period U(1) is an example of a first period, the setting periods U(2) to U(4) are an example of a second period. The lighting maintaining period Uc is an example of a third period. Although the setting period U(1) is longer than the lighting maintaining period Uc in FIG. 15, it is desirable that the lighting maintaining period Uc be set longer than the setting period U(1). This reduces the difference in the light intensity among the laser diodes LD depending on the order of emitting light, compared with the case where the setting period U(1), which is an example of the first period, is longer than the lighting maintaining period Uc, which is an example of the third period.

Referring to FIG. 1, the timing chart in FIG. 15 will be described.

At time a, power is supplied to the controller 110 shown in FIG. 1. As a result, the reference potential Vsub is set to H (0 V), and the power supply potential Vgk is set to L (−3.3 V).

Next, the waveforms of the transfer signals φ1 and φ2, the setting signal φs, and the lighting signals φI1, φI2, φI3, and φI4 will be described. Because the setting periods U(1), U(2), U(3), and U(4) are basically the same, the setting period U(1) will be described.

The transfer signal φ1 is a signal having potentials H (0 V) and L (−3.3 V). The transfer signal φ1 is at H (0 V) at time a in the setting period U(1) and shifts to L (−3.3 V) between times a and b. Then, the transfer signal φ1 returns to H (0 V) at time c. In times c to e, the transfer signal φel repeats the same pattern as in times a to c. Then, the transfer signal φ1 is maintained at H (0 V) from times e to f. In the setting periods U(2) to U(4), the transfer signal φ1 repeats the same pattern as in the setting period U(1).

The transfer signal φ2 is a signal having potentials H (0 V) and L (−3.3 V). The transfer signal φ2 is at H (0 V) at time a in the setting period U(1) and shifts to L (−3.3 V) between times b and c. Then, the transfer signal φ2 returns to H (0 V) at time d. In times d to f, the transfer signal (2 repeats the same pattern as in times b to d. In the setting periods U(2) to U(4), the transfer signal (2 repeats the same pattern as in the setting period U(1).

The setting signal φs is a signal having potentials H (0 V) and L (−3.3 V). The setting signal φs shifts from H (0 V) to L (−3.3 V) when the laser diodes LD shown in FIG. 14 are set to lighting. That is, the setting period U(1) is a period in which all the laser diodes LD11, LD21, LD31, and LD41 are set to lighting. Hence, the setting signal (s is at H (0 V) at time a and shifts to L (−3.3 V) at time b to set the laser diode LD11 to lighting. Then, the setting signal φs returns to H (0 V) between times b and c. Next, the setting signal (s shifts to L (−3.3 V) at time c to set the laser diode LD21 to lighting. Then, the setting signal (s returns to H (0 V) between times b and c. Similarly, the setting signal φs shifts to L (−3.3 V) at time d to set the laser diode LD31 to lighting. Then, the setting signal (s returns to H (0 V) between times d and e. The setting signal φs shifts to L (−3.3 V) at time e to set the laser diode LD41 to lighting. Then, the setting signal φs returns to H (0 V) between times e and f.

The setting signal φs does not shift from H (0 V) to L (−3.3 V) when laser diodes LD are set to non-lighting. For example, in the setting period U(2), the laser diodes LD12 and LD32 are set to lighting, and the laser diodes LD22 and L42 are set to non-lighting. Hence, the setting signal φs shifts to L (−3.3 V) at times g and i, but does not shift to L (−3.3 V) and maintains at H (0 V) at times h and j.

The setting signal φs repeats the same pattern in the setting periods U(3) and U(4).

Specifically, in the setting periods U(1) to U(4), the laser diodes LD to be lit are sequentially turned on. At time u, at which all the laser diodes LD to be lit (emit light) have been sequentially turned on, the laser diodes LD to be lit are turned on in parallel.

As described above, the lighting signals φI1, φI2, φI3, and φI4 are signals having four potentials H (0 V), L1 (−3.1 V), L2 (−2.5 V), and L3 (−3.5 V).

First, the lighting signal φ1 will be described. The lighting signal φI1 is at H (0 V) at time a in the setting period U(1) and shifts to L1 (−3.1 V) between times a and b. Then, at time f, at which the setting period U(1) ends and the setting period U(2) starts, the lighting signal φI1 shifts to L2 (−2.5 V). Then, at time u, at which the setting period U(4) ends and the lighting maintaining period Uc starts, the lighting signal φI1 shifts to L3 (−3.5 V). Then, at time v, at which the lighting maintaining period Uc ends, the lighting signal φI1 returns to H (0 V).

The lighting signal φI2 is at H (0 V) in the setting period U(1) and shifts to L1 (−3.1 V) between times f and g in the setting period U(2). Then, at time k, at which the setting period U(2) ends and the setting period U(3) starts, the lighting signal φI2 shifts to L2 (−2.5 V). Then, at time u, at which the setting period U(4) ends and the lighting maintaining period Uc starts, the lighting signal φ1 shifts to L3 (−3.5 V). Then, at time v, at which the lighting maintaining period Uc ends, the lighting signal φ1 returns to H (0 V).

The lighting signal φI3 is at H (0 V) in the setting periods U(1) and U(2) and shifts to L1 (−3.1 V) between times k and 1 in the setting period U(3). Then, at time p, at which the setting period U(3) ends and the setting period U(4) starts, the lighting signal φI3 shifts to L2 (−2.5 V). Then, at time u, at which the setting period U(4) ends and the lighting maintaining period Uc starts, the lighting signal φ1 shifts to L3 (−3.5 V). Then, at time v, at which the lighting maintaining period Uc ends, the lighting signal I1 returns to H (0 V).

The lighting signal φI4 is at H (0 V) in the setting periods U(1), U(2), and U(3) and shifts to L1 (−3.1 V) between times p and q in the setting period U(4). Then, at time u, at which the setting period U(4) ends and the lighting maintaining period Uc starts, the lighting signal φ1 shifts to L3 (−3.5 V). Then, at time v, at which the lighting maintaining period Uc ends, the lighting signal φI4 returns to H (0 V). The lighting signal φI4 does not have a period in which it is at L2 (−2.5 V).

As described above, the lighting signals φI1 to φI4 have the waveforms that are shifted from one another by the setting period U.

The light intensities of the laser diodes LD11, LD21, LD31, LD41, LD12, LD22, LD32, LD42, LD13, LD23, LD33, LD43, LD14, LD24, LD34, and LD44 when they are lit are indicated by the thickness of the lines. The laser diodes without the lines are in the non-lighting state.

As described above, the light-emitting device 10 operates in accordance with the timing chart shown in FIG. 15. In order to turn off the laser diodes LD that are on, all the lighting signals φI are set to H (0 V) at time v. That is, by repeating the pattern from time a to v, lighting and non-lighting of the laser diodes LD are controlled in time series.

Although L1 (−3.1 V) and L3 (−3.5 V) are different potentials in the above description, L1 and L3 may be the same potential.

For stable operation of the light-emitting unit 100, the gates Gs and the power supply potential Vgk, or the gates Gd (wire 76) and the power supply potential Vgk may be connected to each other via resistors.

The coupling diodes D may be transistors. Diodes may be connected in series to the anode sides of the setting thyristors S and the transfer thyristors T. To adjust the driving voltages corresponding to these changes, diodes and resistors may be added in the light-emitting unit 100 to stabilize the operation. In addition, a resistance component may be provided between the p gate layer 87 of the drive thyristor DT and the wire 76, so that the voltage of the gate Gd of the drive thyristor DT in the on state is less likely to affect the gates Gd of the other drive thyristors DT in the on state sharing the wire 76.

The pads (the φ1, φ2, Vgk, φs, and φIj terminals) may be provided substantially parallel to the transfer thyristors T on the substrate 80 of the light-emitting device 10. This allows the current and/or the voltage to be uniformly supplied depending on the arrangement of the laser diodes LD.

Furthermore, by providing the multiple terminals (φ1, φ2, Vgk, φs, and φIj terminals) on a thick insulating film made of Benzocyclobutene (BCB), for example, and provided on the transfer element unit 105 (see FIG. 1), the size and cost are reduced. In addition, the light from the transfer thyristors T and the setting thyristors S is blocked.

Although the number of transfer thyristors T and the number of setting thyristors S have been described as the same, using the letter i, multiple setting thyristors S may be connected to one transfer thyristor T, or multiple setting signal wires 75 may be provided to increase the speed of driving. Furthermore, multiple light-emitting units 100 may be arranged on the same substrate or multiple divided substrates and driven in parallel. This increases the speed of driving.

In the light-emitting unit 100 and the light-emitting device 10 described in detail above, the exit-surface protective films 351 are provided on the inner surfaces of the openings δ. This provides the light-emitting unit 100 and the light-emitting device 10 that are less likely to malfunction even when some kind of light, such as external light, enters the openings δ.

### Optical Measurement Device 1

The above-described light-emitting device 10 can be used for optical measurement.

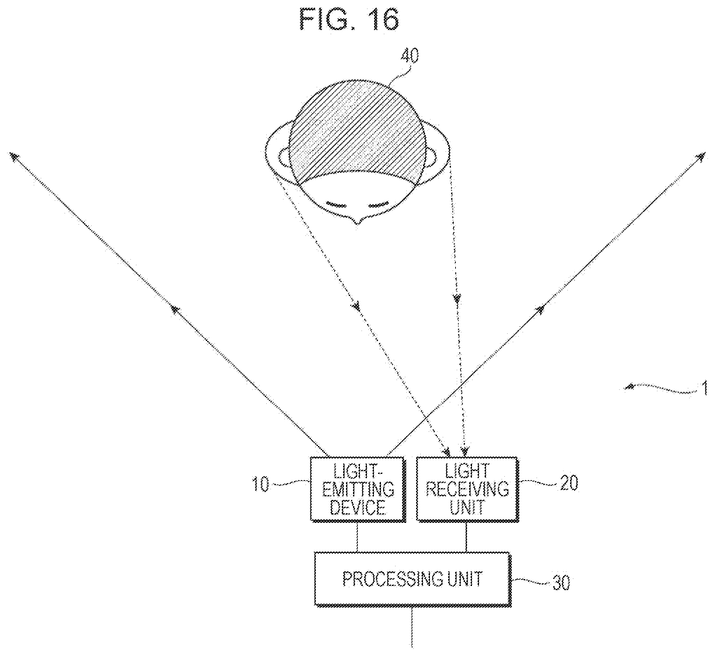

FIG. 16 shows an optical measurement device 1 using the light-emitting device 10.

The optical measurement device 1 includes the above-described light-emitting device 10, a light receiving unit 20 that receives light, and a processing unit 30 that processes data. A measurement object (object) 40 is placed so as to face the optical measurement apparatus 1. In FIG. 16, the measurement object 40 is, for example, a person. FIG. 16 is a view from above.

The light-emitting device 10 turns on the laser diodes LD arranged two-dimensionally as described above to emit light spreading conically from the light-emitting device 10, as indicated by solid lines. At this time, multiple lighting signals φIj may be simultaneously set to L1 (−3.1 V) or L3 (−3.5 V) as in the setting period U(1) or the lighting maintaining period Uc from the beginning.

The light receiving unit 20 is a device that receives light reflected by the measurement object 40. The light receiving unit 20 receives light traveling toward the light receiving unit 20, as indicated by broken lines. Desirably, the light receiving unit 20 is an imaging device that receives light from two-dimensional directions.

The processing unit 30 is a computer including an input/output unit via which data is input and output. The processing unit 30 processes information related to the light to calculate the distance to the measurement object 40 and the three-dimensional shape of the measurement object 40.

The processing unit 30 of the optical measurement device 1 controls and causes the light-emitting device 10 to emit light in a short period. That is, the light-emitting device 10 emits pulsed light. Then, the processing unit 30 calculates the optical path length from when the light is emitted from the light-emitting device 10 to when the light reaches the light receiving unit 20 after being reflected by the measurement object 40, from the difference between the timing (time) when the light-emitting device 10 emits the light and the timing (time) when the light receiving unit 20 receives the reflected light from the measurement object 40. The positions of the light-emitting device 10 and the light receiving unit 20 and the distance therebetween are set in advance. Hence, the processing unit 30 measures (calculates) the distance from the light-emitting device 10 and the light receiving unit 20 or from a point serving as a reference (reference point) to the measurement object 40. The reference point is a point set at a certain distance from the light-emitting device 10 and the light receiving unit 20.

This measurement method is based on the traveling time of light and is called a time-of-flight (TOF) method.

By measuring multiple points of the measurement object 40 with this method, the three-dimensional shape of the measurement object 40 is measured. As described above, the light emitted from the light-emitting device 10 is radiated on the measurement object 40 while spreading two-dimensionally. Then, the reflected light coming from a portion of the measurement object 40 close to the light-emitting device 10 first enters the light receiving unit 20. When the above-mentioned imaging device for acquiring a two-dimensional image is used, bright spots are recorded in frames, at portions at which the reflected light arrives. From the bright spots recorded in a series of frames, the optical path length for each bright spot is calculated. Then, the distance from the light-emitting device 10 and the light receiving unit 20 or from the point serving as the reference (reference point) is calculated. Specifically, the three-dimensional shape of the measurement object 40 is calculated.

The light-emitting device 10 according to this exemplary embodiment may also be used in an optical survey method using a structured light method. This method uses substantially the same devices as in the optical measurement device 1 using the light-emitting device 10 shown in FIG. 16, except that the measurement object 40 is irradiated with a random pattern consisting of an infinite number of dots of light, and the reflected light is received by the light receiving unit 20. The processing unit 30 processes information related to the light. In the processing, instead of the time difference described above, the positional deviations of the infinite number of dots of light are calculated to obtain the distance to the measurement object 40 and the three-dimensional shape of the measurement object 40. A randomly arranged two-dimensional VCSEL array or the like is conventionally used as a light source in this method, and there are about one to four predetermined random patterns to be radiated (structured Fix method). In contrast, the light-emitting device 10 according to this exemplary embodiment can radiate more random patterns, because the dots of light to be radiated can be freely set by signals from the outside.

The optical measurement device 1 as described above can be used to calculate the distance to an article. In addition, the optical measurement device 1 can be used to calculate the shape of an article to identify the article. The optical measurement device 1 can be used to calculate the shape of a human face to identify the face (face authentication). In addition, the optical measurement device 1 can be mounted on a vehicle and used to detect an obstacle in front of, behind, and beside the vehicle. The optical measurement device 1 can be widely used to calculate the distance, shape, and the like.

### Image Forming Apparatus 2

The light-emitting device 10 described above can be used for image formation.

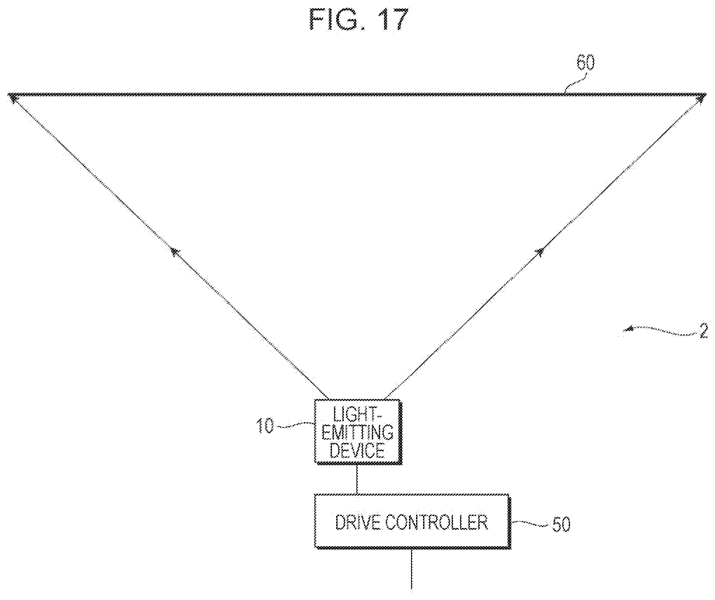

FIG. 17 shows an image forming apparatus 2 using the light-emitting device 10.

The image forming apparatus 2 includes the light-emitting device 10, a drive controller 50, and a screen 60 that receives light.

The operation of the image forming apparatus 2 will be described.

As described above, the light-emitting device 10 sets the two-dimensionally arranged laser diodes LD to lighting and non-lighting. Then, the laser diodes LD are turned on in parallel in the lighting maintaining period Uc. That is, a two-dimensional still image (two-dimensional image) is obtained. Hence, as a result of the drive controller 50, which receives an input of an image signal and drives the light-emitting device 10 according to the image signal such that the two-dimensional image is formed, sequentially rewriting the two-dimensional image every lighting maintaining period Uc, serving as frame, a moving two-dimensional image is obtained. These still and moving two-dimensional images are projected on the screen 60.

In the above description, the laser diodes LD in the off state are turned on (to emit light), but the light intensity in the light-emitting state may be increased.

The foregoing description of the exemplary embodiments of the present disclosure has been provided for the purposes of illustration and description. It is not intended to be exhaustive or to limit the disclosure to the precise forms disclosed. Obviously, many modifications and variations will be apparent to practitioners skilled in the art. The embodiments were chosen and described in order to best explain the principles of the disclosure and its practical applications, thereby enabling others skilled in the art to understand the disclosure for various embodiments and with the various modifications as are suited to the particular use contemplated. It is intended that the scope of the disclosure be defined by the following claims and their equivalents.

What is claimed is:

1. A light-emitting component comprising:
a substrate; and
a light-emitting element provided on the substrate and configured to emit light in a direction intersecting a surface of the substrate, wherein:
the light-emitting element includes a thyristor having an opening through which light is emitted, and
an inner surface of the opening is covered with a light shield that suppresses transmission of light.

2. The light-emitting component according to claim 1, wherein:
the light shield is made of a metal, and
an insulating portion is provided between the thyristor and the light shield.

3. The light-emitting component according to claim 2, wherein the light shield extends from an electrode electrically connected to the thyristor to the inner surface of the opening.

4. The light-emitting component according to claim 2, wherein the light shield extends from a current supply wire electrically connected to the thyristor to the inner surface of the opening.

5. The light-emitting component according to claim 1, wherein the light shield is made of an insulator.

6. The light-emitting component according to claim 1, wherein:
the light-emitting element further includes an electrode, and
the light shield further covers the electrode.

7. The light-emitting component according to claim 1, wherein the light shield is made of a metal and covers the electrode with an insulating portion therebetween.

8. The light-emitting component according to claim 1, wherein the light shield is a light absorbing body that absorbs light.

9. The light-emitting component according to claim 8, wherein at least one of layers constituting the thyristor absorbs light having a longer wavelength than the emitted light.

10. The light-emitting component according to claim 1, wherein the light shield covers a portion of the inner surface of the opening.

11. The light-emitting component according to claim 1, wherein the light shield is a light reflector that reflects light.

12. An optical measurement device comprising:
the light-emitting component according to claim 1;
a light-receiving unit configured to receive light reflected from an object irradiated with the light emitted from the light-emitting component; and
a processing unit configured to process information related to the light received by the light-receiving unit to measure the distance from the light-emitting component to the object or the shape of the object.

13. An optical measurement device comprising:
the light-emitting component according to claim 2;
a light-receiving unit configured to receive light reflected from an object irradiated with the light emitted from the light-emitting component; and
a processing unit configured to process information related to the light received by the light-receiving unit to measure the distance from the light-emitting component to the object or the shape of the object.

14. An optical measurement device comprising:
the light-emitting component according to claim 3;
a light-receiving unit configured to receive light reflected from an object irradiated with the light emitted from the light-emitting component; and
a processing unit configured to process information related to the light received by the light-receiving unit to measure the distance from the light-emitting component to the object or the shape of the object.

15. An image forming apparatus comprising:
the light-emitting component according to claim 1; and
a drive controller configured to receive input of an image signal and drive the light-emitting component according to the image signal so that a two-dimensional image is formed by the light emitted from the light-emitting component.

16. A method for manufacturing a light-emitting component, the method comprising, in this sequence:
forming layers to form a thyristor on a substrate;
providing, in the thyristor, an opening through which light is emitted in a direction intersecting a surface of the substrate; and
covering the thyristor and an inner surface of the opening with a light shield that suppresses transmission of light.

17. The method for manufacturing the light-emitting component according to claim 16, wherein the light shield is made of a metal and is formed as an electrode so as to extend from the inner surface of the opening over the thyristor.

18. The method for manufacturing the light-emitting component according to claim 16, wherein the light shield is made of a metal and is formed, as a current supply wire electrically connected to the thyristor, so as to extend from the inner surface of the opening over the thyristor.

19. A method for manufacturing a light-emitting component, the method comprising, in this sequence:
forming layers to form a thyristor on a substrate;
forming an electrode on the thyristor;
providing, in the thyristor, an opening through which light is emitted in a direction intersecting a surface of the substrate; and
covering the thyristor and an inner surface of the opening with a light shield that suppresses transmission of light.

20. The method for manufacturing the light-emitting component according to claim 19, wherein the light shield is made of a metal and is formed so as to cover the electrode with an insulating portion therebetween.
